(19) United States
(12) Patent Application Publication
(10) Pub. No.: US 2025/0287600 A1
(43) Pub. Date: Sep. 11, 2025

(54) SEMICONDUCTOR DEVICES HAVING CAPACITOR STRUCTURES

(71) Applicant: SAMSUNG ELECTRONICS CO., LTD., Suwon-si (KR)

(72) Inventors: Taegon Lee, Suwon-si (KR); Kangin Lee, Suwon-si (KR); Jieun Ha, Suwon-si (KR); Minkyu Kang, Suwon-si (KR)

(21) Appl. No.: 18/885,142

(22) Filed: Sep. 13, 2024

(30) Foreign Application Priority Data
Mar. 8, 2024 (KR) 10-2024-0033310

(51) Int. Cl. H10B 43/40; G11C 16/30; H10B 41/27; H10B 41/41; H10B 43/27

(52) U.S. Cl. CPC H10B 43/40; G11C 16/30; H10B 41/27; H10B 41/41; H10B 43/27

(57) ABSTRACT

An example semiconductor device includes a first semiconductor structure and a second semiconductor structure. The first semiconductor structure includes a substrate, an active region within the substrate, circuit elements on the substrate, an element isolation region defining the active region, impurity regions disposed within the active region on both sides of the circuit elements, an interconnection structure electrically connected with the circuit elements, and a capacitor structure spaced apart from the interconnection structure in a first direction. The second semiconductor structure includes a plate layer disposed on the first semiconductor structure, gate electrodes sequentially stacked and spaced apart from each other in a direction, perpendicular to an upper surface of the plate layer, on the plate layer, and channel structures extending through the gate electrodes in the perpendicular direction.

### CROSS-REFERENCE TO RELATED APPLICATION

This application claims benefit of priority to Korean Patent Application No. 10-2024-0033310 filed on Mar. 8, 2024, in the Korean Intellectual Property Office, the disclosure of which is incorporated herein by reference in its entirety.

### BACKGROUND

In a data storage system requiring data storage, a semiconductor device capable of storing high-capacitance data is required. Accordingly, a manner to increase the data storage capacitance of semiconductor devices has been researched. Additionally, highly integrated semiconductor devices are in demand. For example, as one of the methods to increase the degree of integration of a semiconductor device, a semiconductor device, in which memory cells and a peripheral circuit region are arranged vertically, has been proposed.

### SUMMARY

The present disclosure relates to a semiconductor device including a capacitor structure with improved integration and electrical characteristics.

The object of the present application is not limited to the foregoing content and may be variously extended without departing from the spirit and domain of the present disclosure.

In some implementations, a semiconductor device includes a first semiconductor structure including a substrate, an active region within the substrate, circuit elements on the substrate, an element isolation region defining the active region, impurity regions disposed within the active region on both sides of the circuit elements, an interconnection structure electrically connected to the circuit elements, and a capacitor structure spaced apart from the interconnection structure in a first direction, and a second semiconductor structure including a plate layer disposed on the first semiconductor structure, gate electrodes sequentially stacked and spaced apart from each other in a direction, perpendicular to an upper surface of the plate layer, on the plate layer, and channel structures penetrating through the gate electrodes and extending in the perpendicular direction, wherein the capacitor structure may include: a first electrode structure including a first strap portion disposed on the substrate and extending in the first direction, and first electrodes extending from the first strap portion in a second direction, intersecting the first direction; and a second electrode structure including a second strap portion extending on the substrate in the first direction and spaced apart from the first strap portion in the second direction, and second electrodes extending from the second strap portion in the second direction and arranged alternately with the first electrodes, and the first electrodes may have a plate shape extending from an upper surface of the first strap portion in a vertical direction, intersecting the first direction and the second direction, and the second electrodes may have a plate shape extending from an upper surface of the second strap portion in the vertical direction.

In some implementations, a semiconductor device includes a substrate including an active region; circuit elements on the active region; an element isolation region defining the active region; impurity regions disposed inside the active region on both sides of the circuit elements; a capacitor structure spaced apart from the circuit elements; and a first finger trench spaced apart from the circuit elements and extending inside the substrate in a first direction, and a second finger trench extending in the first direction and arranged alternately with the first finger trench, wherein the capacitor structure may include: first lower electrodes disposed on the first finger trench; and second lower electrodes disposed on the second finger trench and arranged alternately with the first lower electrodes, wherein the first lower electrodes and the second lower electrodes may have a plate shape extending in the first direction and a vertical direction, intersecting the first direction, and an upper surface of the first finger trench and an upper surface of the second finger trench may be disposed on the same level as an upper surface of the element isolation region.

In some implementations, a semiconductor device includes a substrate including an active region; circuit elements including a gate structure on the active region; an element isolation region defining the active region; impurity regions disposed inside the active region on both sides of the circuit elements; and a capacitor structure spaced apart from the circuit elements, wherein the capacitor structure may include: a first electrode structure including a first strap portion disposed on the substrate and extending in a first direction, and first electrodes extending from the first strap portion in a second direction, intersecting the first direction; and a second strap portion including a second strap portion extending on the substrate in the first direction and spaced apart from the first strap portion in the second direction, and second electrodes extending from the second strap portion in the second direction and arranged alternately with the first electrodes, wherein an upper surface of the first strap portion and an upper surface of the second strap portion may be disposed on at the same level as an upper surface of the gate structure.

In some implementations, a semiconductor device includes a capacitor structure, and the capacitor structure may be disposed on a substrate and includes lower electrodes having a relatively high vertical height to secure electrostatic capacity, thereby providing a semiconductor device with improved electrical characteristics.

In some implementations, a semiconductor device includes a capacitor structure including first and second strap portions provided in the same process as a circuit element, first lower electrodes connected through the first strap portion, and second lower electrodes arranged alternately with the first lower electrodes and connected through the second strap portion. Accordingly, the semiconductor device may form a routing interconnection applied to the capacitor structure through the first and second strap portions extending between a peripheral interconnection and the lower electrodes, a semiconductor device having improved integration may be provided.

Advantages and effects of the present application are not limited to the foregoing content and may be variously extended without departing from the spirit and domain of the present disclosure.

### BRIEF DESCRIPTION OF THE DRAWINGS

The above and other aspects, features, and advantages of the present disclosure will be more clearly understood from the following detailed description, taken in conjunction with the accompanying drawings.

FIG. 1A is a schematic block diagram of an example of a semiconductor device.

FIG. 1B is a circuit diagram illustrating an example of a charge pump circuit included in a voltage generator of a semiconductor device.

FIG. 1C is a schematic perspective view of an example of a semiconductor device.

FIG. 1D is a cross-sectional view of an example of a semiconductor device.

FIG. 1E is a cross-sectional view of an example of a semiconductor device.

FIG. 2A is a schematic perspective view illustrating an example of a capacitor structure of a semiconductor device.

FIG. 2B is a perspective view illustrating an example of a semiconductor device including the capacitor structure of FIG. 2A.

FIG. 2C is a perspective view illustrating another example of a semiconductor device including the capacitor structure of FIG. 2A.

FIG. 3A is a schematic perspective view illustrating another example of a capacitor structure of a semiconductor device.

FIG. 3B is a perspective view illustrating an example of a semiconductor device including the capacitor structure of FIG. 3A.

FIG. 4A is a schematic perspective view illustrating another example of a capacitor structure of a semiconductor device.

FIG. 4B is a perspective view illustrating an example of a semiconductor device including the capacitor structure of FIG. 4A.

FIG. 5A is a schematic perspective view illustrating another example of a capacitor structure of a semiconductor device.

FIG. 5B is a plan view illustrating an example of a semiconductor device including the capacitor structure of FIG. 5A.

FIG. 5C is a cross-sectional view illustrating an example taken along line I-I′ of the semiconductor device of FIG. 5B.

FIGS. 6A, 6B, and 6C are views illustrating an example of a method of manufacturing the semiconductor device of FIG. 5B.

FIG. 7 is a view schematically illustrating an example of a data storage system including a semiconductor device.

### DETAILED DESCRIPTION

Hereinafter, example implementations of the present disclosure will be described with reference to the accompanying drawings. The same reference numerals are used for the same components in the drawings, and duplicate descriptions for the same components are omitted.

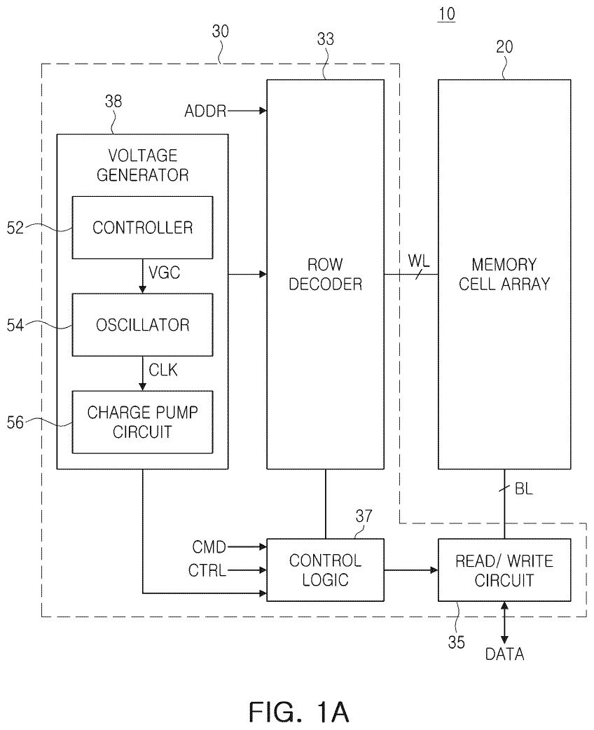

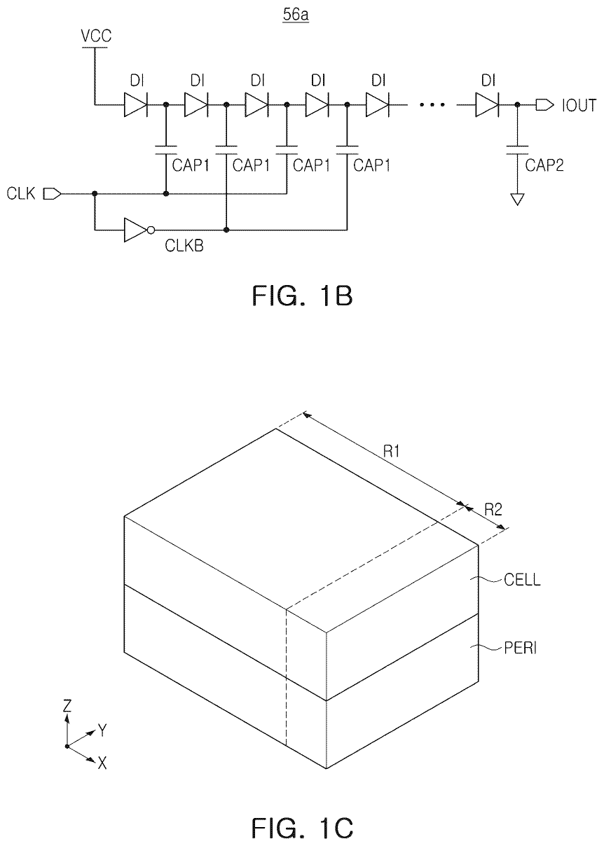

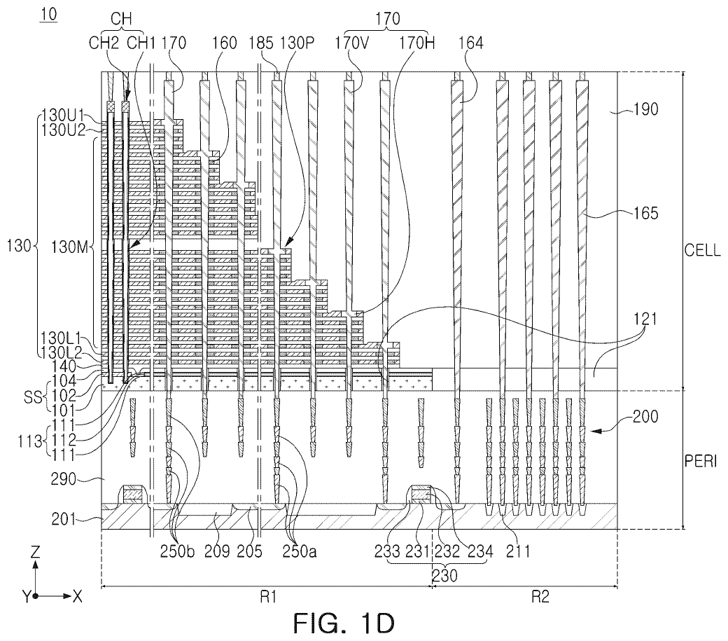

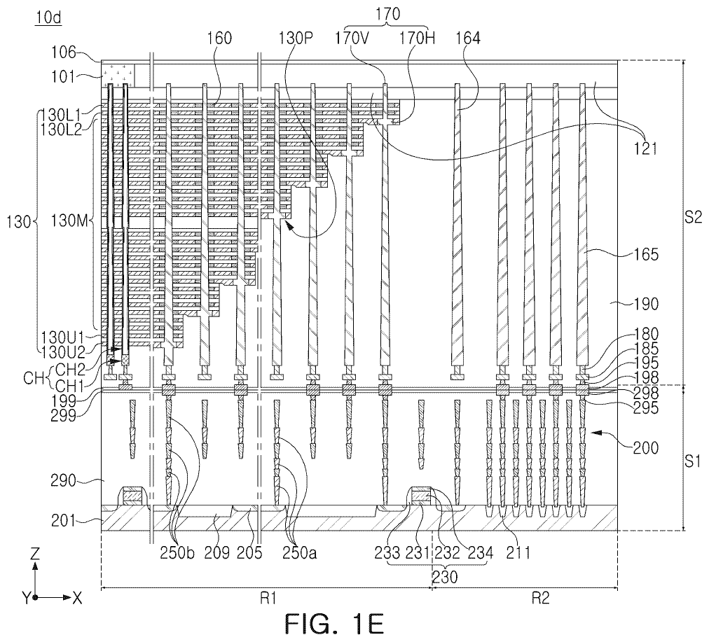

FIG. 1A is a schematic block diagram of an example of a semiconductor device. FIG. 1B is a circuit diagram illustrating an example of a charge pump circuit included in a voltage generator of a semiconductor device. FIG. 1C is a schematic perspective view of an example of a semiconductor device.

Referring to FIG. 1A, a semiconductor device 10 may include a memory cell array 20 and a peripheral circuit 30. The semiconductor device 10 may be a memory device, for example, a non-volatile memory such as a flash memory, or a volatile memory such as a dynamic random access memory (DRAM) or a static random access memory (SRAM).

The memory cell array 20 may include a plurality of memory cells. The plurality of memory cells may be connected to a row decoder 33 through a plurality of word lines WL, and may be connected to a read/write circuit 35 through bit lines BL. In an example, a plurality of memory cells arranged along the same row may be connected to the same word line WL, and a plurality of memory cells arranged along the same column may be connected to the same bit line BL. In some implementations, the memory cell array 20 may include a plurality of memory blocks, and each of the memory blocks may include a plurality of memory cells.

The peripheral circuit 30 may receive an address ADDR, a command CMD, and a control signal CTRL from the outside of the semiconductor device 10, and may transmit and receive data DATA with an external device of the semiconductor device 10. The peripheral circuit 30 may include a row decoder 33, a read/write circuit 35, a control logic 37, and a voltage generator 38 generating various voltages required for an operation. According to some implementations, the peripheral circuit 30 may further include various sub-circuits, such as an input/output circuit and an error correction circuit for correcting errors in data DATA read from the memory cell array 20.

The control logic 37 may be connected to the row decoder 33, the voltage generator 38, and the input/output circuit. The control logic 37 may control an overall operation of the semiconductor device 10. The control logic 37 may generate various internal control signals used in the semiconductor device 10 in response to the control signal CTRL. For example, the control logic 37 may adjust a voltage level provided to word lines WL and bit lines BL when performing a memory operation such as a program operation or an erase operation.

The row decoder 33 may select some of the plurality of memory cells in response to the address ADDR, and may select at least one word line WL. The row decoder 33 may transmit a voltage for performing a memory operation to the selected word line WL.

The read/write circuit 35 may be connected to the memory cell array 20 through the bit lines BL. The read/write circuit 35 may include a writer driver or a sense amplifier. Specifically, during a program operation, the read/write circuit 35 may operate as a write driver and apply a voltage according to the data DATA to be stored in the memory cell array 20 to the bit lines BL. Meanwhile, during a read operation, the read/write circuit 35 operates as a sense amplifier and may detect data DATA stored in the memory cell array 20.

The voltage generator 38 may include a controller 52, an oscillator 54, and a charge pump 56.

The charge pump 56 may include a plurality of charge pumps, and each of the plurality of charge pumps may include at least one switch element and at least one pumping capacitor. The charge pump 56 may provide current through the row decoder 33 to apply an operating voltage to the word line WL of the memory cell array.

The controller 52 may control an operation of the oscillator 54. For example, the controller 52 may determine one select charge pump among the plurality of charge pumps, based on at least one of PVT (Process, Voltage, Temperature) information of the semiconductor device 10 and a target level of a power supply voltage to be supplied. The controller 52 may deactivate the remaining charge pumps except the selected charge pump.

The oscillator 54 may output a clock signal CLK. The oscillator 54 may operate in response to a control signal VGC from the controller 52. For example, the oscillator 54 may output the clock signal CLK to at least some of the plurality of charge pumps, in response to the control signal VGC transmitted by the controller 52.

FIG. 1B is a circuit diagram illustrating an example of a charge pump circuit included in a voltage generator of a semiconductor device.

Referring to FIG. 1B, a charge pump circuit 56a may include a plurality of diodes DI, a plurality of pumping capacitors CAP1, and an output capacitor CAP2. The plurality of diodes DI may be connected to each other in series, and the plurality of pumping capacitors CAP1 may be connected to nodes between the plurality of diodes DI. A first diode may receive a power supply voltage VCC having a predetermined level, and a last diode may transmit an output current IOUT to an output node.

Each of the plurality of pumping capacitors CAP1 may be charged or discharged by the clock signal CLK and a complementary clock signal CLKB phase-converted to have an opposite phase by the clock signal CLK and an inverter INV. For example, odd-numbered pumping capacitors CAP1 may be charged or discharged by the clock signal CLK, and even-numbered pumping capacitors CAP1 may be charged or discharged by the complementary clock signal CLKB.

FIG. 1C is a schematic perspective view of an example of a semiconductor device.

Referring to FIG. 1C, the semiconductor device 10 may include a peripheral circuit structure PERI and a memory cell structure CELL. The memory cell structure CELL may be disposed on the peripheral circuit structure PERI. The memory cell structure CELL may be disposed on the peripheral circuit structure PERI. The memory cell structure CELL may be a region in which the memory cell array 20 of FIG. 1A is disposed, and the peripheral circuit structure PERI may be a region in which the peripheral circuit 30 of FIG. 1A is disposed. In some implementations, on the contrary, the memory cell structure CELL may be disposed below the peripheral circuit structure PERI.

The memory cell structure CELL may include a first region R1 and a second region R2.

The first region R1 of the memory cell structure CELL may be a region in which the memory cell array 20 is disposed. The second region R2 of the memory cell structure CELL may correspond to a region for electrically connecting memory cells of the memory cell array 20 to the peripheral circuit 30. The second region R2 may be disposed in at least one end of the first region R1 in at least one direction, for example, the first direction (X-direction).

A plurality of pumping capacitors CAP1 included in the charge pump circuits 56 and 56a of FIGS. 1A and 1B may be disposed in the peripheral circuit structure PERI. For example, the plurality of pumping capacitors CAP1 may be disposed below the second region R2 of the memory cell structure CELL in the peripheral circuit structure PERI, but the present invention is not limited thereto. In another example, the plurality of pumping capacitors CAP1 may be disposed below the first region R1 of the memory cell structure CELL in the peripheral circuit structure PERI. FIG. 1D is a cross-sectional view of an example of a semiconductor device.

Referring to FIG. 1D, the semiconductor device 10 may include a peripheral circuit structure PERI which is a first semiconductor structure including a substrate 201, and a memory cell structure CELL which is a second semiconductor structure including a plate layer 101.

The peripheral circuit structure PERI may include the substrate 201, impurity regions 205 and element isolation regions 209 within the substrate 201, circuit elements 230 disposed on the substrate 201, a peripheral region insulating layer 290, and interconnection structures 250a and 250b. In an example, the peripheral circuit structure PERI may further include an insulating trench 211 within the substrate 201 and a capacitor structure 200 disposed on the insulating trench 211.

The substrate 201 may have an upper surface extending in the first direction (X-direction) and a second direction (Y-direction). An active region may be defined on the substrate 201 by element isolation regions 209. Impurity regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer. For example, the substrate 201 may be bulk silicon or silicon-on-insulator SOI.

The circuit elements 230 may include planar transistors. Each of the circuit element 230 may include a peripheral gate dielectric layer 231, a peripheral gate electrode 232 on the peripheral gate dielectric layer 231, a peripheral gate capping layer 234 and a peripheral gate dielectric layer 231 disposed on the peripheral gate electrode 232, a peripheral gate electrode 232, and a peripheral gate spacer 233 on a side surface of the peripheral gate capping layer 234. The impurity regions 205 may be disposed as source/drain regions in the substrate 201 on both sides of the peripheral gate electrode 232.

The peripheral region insulating layer 290 may be disposed on the circuit element 230 on the substrate 201. The peripheral region insulating layer 290 may include a plurality of insulating layers formed in different process operations. The peripheral region insulating layer 290 may be formed of an insulating material.

The interconnection structures 250a and 250b may include a contact plug 250a and interconnections 250b. However, the present disclosure is not limited thereto, and the structure of the interconnection structures 250a and 250b may be variously changed. The interconnection structures 250a and 250b may be electrically connected to the circuit elements 230 and the impurity regions 205. The interconnection structures 250a and 250b may be referred to as lower interconnection structures or circuit interconnection structures. The contact plug 250a may have a pillar shape, and the interconnections 250b may have a line shape. An electrical signal may be applied to the circuit element 230 through the interconnection structures 250a and 250b. The contact plug 250a may also be connected to the peripheral gate electrode 232 in a region not illustrated. The interconnections 250b may be connected to the contact plug 250a and may be arranged in a plurality of layers. The contact plug 250a and the interconnections 250b may include a conductive material. For example, the contact plug 250a and the interconnections 250b may include tungsten (W), copper (Cu), or aluminum (Al), and each of the components may further include a diffusion barrier.

The capacitor structure 200 may be spaced apart from the interconnection structures 250a and 250b and may be disposed on the second region R2 of the peripheral circuit structure PERI. The capacitor structure 200 may be disposed on the insulating trench 211 of the substrate 201. The capacitor structure 200 may perform a function of storing electric charges. The capacitor structure 200 may form the pumping capacitor CAP1 of the charge pump circuits 56 and 56a described above with reference to FIGS. 1A to 1C.

The memory cell structure CELL may have first and second regions R1 and R2, and may include a source structure SS, gate electrodes 130 stacked on the source structure SS, interlayer insulating layers 140 stacked alternately with the gate electrodes 130, channel structures CH arranged to penetrate through a stack structure of the gate electrodes 130, and contact plugs 170 connected to the gate electrodes 130 and extending vertically. The memory cell structure CELL may further include a horizontal insulating layer 113 disposed below the gate electrodes 130, substrate insulating layers 121 arranged to penetrate through the plate layer 101, studs 180 on the contact plugs 170, and a cell region insulating layer 190 covering the gate electrodes 130.

In the memory cell structure CELL, the first region R1 may be a region in which the gate electrodes 130 are vertically stacked to form memory cells or are connected to contact plugs 170. The second region R2 may be an outer region of the plate layer 101.

The source structure SS may include the plate layer 101, a first horizontal conductive layer 102, and a second horizontal conductive layer 104, which are sequentially stacked. The plate layer 101 has a plate shape, and may function as at least a portion of a common source line of a semiconductor device 100. The plate layer 101 may include a conductive material, for example, a semiconductor material. The plate layer 101 may further include impurities. The plate layer 101 may be provided as a polycrystalline semiconductor layer, such as a polycrystalline silicon layer, or an epitaxial layer.

The first and second horizontal conductive layers 102 and 104 may be sequentially stacked and disposed on an upper surface of the plate layer 101, in a region in which the channel structures CH are disposed. The first horizontal conductive layer 102 may function as a portion of the common source line of the semiconductor device 100, and, for example, may function as a common source line together with the plate layer 101. The first horizontal conductive layer 102 may be directly connected to a channel layer in the channel structure CH. The first and second horizontal conductive layers 102 and 104 may include a semiconductor material, for example, polycrystalline silicon.

The horizontal insulating layer 113 may be disposed on the plate layer 101 on the same level as the first horizontal conductive layer 102. The horizontal insulating layer 113 may include first and second horizontal insulating layers 111 and 112 alternately stacked on the plate layer 101. The horizontal insulating layer 113 may be layers that remain after a portion of the horizontal insulating layer 113 is replaced with the first horizontal conductive layer 102 during a manufacturing process of the semiconductor device 100. The horizontal insulating layer 113 may include silicon oxide, silicon nitride, silicon carbide, or silicon oxynitride. The first horizontal insulating layers 111 and the second horizontal insulating layers 112 may include different insulating materials.

The substrate insulating layers 121 may penetrate through the plate layer 101, the horizontal insulating layer 113, and the second horizontal conductive layer 104. The substrate insulating layer 121 may include an insulating material, for example, silicon oxide, silicon nitride, silicon carbide, or silicon oxynitride.

The gate electrodes 130 may be vertically spaced apart from each other and stacked on the plate layer 101 to form a stack structure together with the interlayer insulating layers 140. The stack structure may include lower and upper stack structures vertically stacked. The gate electrodes 130 may include first upper gate electrodes 130U1 and 130U2 of string selection transistors, memory gate electrodes 130M of a plurality of memory cells, and second lower gate electrodes 130L1 and 130L2 of a ground selection transistor. The number of memory gate electrodes 130M of the memory cells may be determined according to the capacitance of the semiconductor device 100.

The gate electrodes 130 may be vertically spaced apart from each other and stacked on the first region R1, and may extend to different lengths in the first direction (X-direction) to form a step structure in a stepwise shape. Due to the step structure, a lower gate electrode 130 of the gate electrodes 130 may extend to be longer than an upper gate electrode 130 thereof, and may each have contact regions 130P exposed upwardly from the interlayer insulating layers 140. The gate electrodes 130 may be respectively connected to the contact plugs 170 in contact regions 130P which are end regions.

The gate electrodes 130 may include a metal material, for example, tungsten (W). According to some implementations, the gate electrodes 130 may include a polycrystalline silicon or metal silicide material. The gate electrodes 130 may entirely include the same material. In some implementations, the gate electrodes 130 may further include a diffusion barrier, for example, the diffusion barrier may include tungsten nitride (WN), tantalum nitride (TaN), or titanium nitride (TiN), or a combination thereof.

The interlayer insulating layers 140 may be disposed between the gate electrodes 130. Similarly to the gate electrodes 130, the interlayer insulating layers 140 may be spaced apart from each other in a direction, perpendicular to the upper surface of the plate layer 101, and may extend in the first direction (X-direction). The interlayer insulating layers 140 may include an insulating material such as silicon oxide or silicon nitride.

The channel structures CH may extend in the third direction (Z-direction) through the gate electrodes 130, and may be connected to the plate layer 101. Each of the channel structures CH may form one memory cell string, and the channel structures CH may be spaced apart from each other in rows and columns on the plate layer 101. The channel structures CH may be arranged to form a grid pattern in an X-Y plane or may be arranged in a zigzag shape in one direction. The channel structures CH may have a pillar shape and may have inclined side surfaces that become narrower as they approach the plate layer 101.

The channel structures CH may include vertically stacked lower and upper channel structures CH1 and CH2. The channel structures CH may have a shape in which the lower channel structures CH1 and the upper channel structures CH2 are connected, and may have bent portions due to differences in width in a connection region. However, according to some implementations, the number of channel structures stacked in the third direction (Z-direction) may be variously changed. Each of the channel structures CH may include a channel layer disposed in a channel hole, a gate dielectric layer, a channel buried insulating layer, and a channel pad on an upper end.

The contact plugs 170 may be connected to the contact regions 130P of the gate electrodes 130. The contact plugs 170 may penetrate through at least a portion of the cell region insulating layer 190, and may be connected to each of the contact regions 130P of the gate electrodes 130 exposed upwardly. The contact plugs 170 may penetrate through the gate electrodes 130 below the contact regions 130P, and may penetrate through the second horizontal conductive layer 104, the horizontal insulating layer 113, and the plate layer 101 and may be connected to a lower interconnection structure 250 in the peripheral circuit structure PERI.

The contact plugs 170 may be spaced apart from the gate electrodes 130 below the contact regions 130P by the contact insulating layers 160. The contact plugs 170 may be spaced apart from the plate layer 101, the horizontal insulating layer 113, and the second horizontal conductive layer 104 by the substrate insulating layers 121.

Each of the contact plugs 170 may have a shape that extends horizontally in the contact area 130P. The contact plug 170 may include a vertical extension portion 170V extending in the vertical direction (Z-direction) and a horizontal extension portion 170H that extends horizontally from the vertical extension portion 170V and is in contact with the gate electrode 130. The horizontal extension portion 170H may be disposed along a circumference of the vertical extension portion 170V, and all side surfaces thereof may be surrounded by the gate electrode 130. The contact plugs 170 may be spaced apart from the gate electrodes 130 below the contact regions 130P, that is, gate electrodes 130 that are not electrically connected, by the contact insulating layers 160.

The contact plugs 170 may include a conductive material, for example, at least one of tungsten (W), copper (Cu), aluminum (Al), and alloys thereof. In some implementations, the contact plugs 170 may include a barrier layer extending along a side surface and a bottom surface thereof, or may have an air gap therein.

The contact insulating layers 160 may be arranged to surround side surfaces of each of the contact plugs 170 below the contact regions 130P. The contact insulating layers 160 may be spaced apart from each other in the third direction (Z-direction) around each of the contact plugs 170. The contact insulating layers 160 may be disposed on substantially the same level as the gate electrodes 130. The contact insulating layers 160 may include an insulating material, for example, silicon oxide, silicon nitride, or silicon oxynitride.

The studs 180 may be included in a cell interconnection structure that is electrically connected to memory cells in the memory cell structure CELL. The studs 180 may be connected to the channel structures CH and the contact plugs 170, and may be electrically connected to the channel structures CH and the gate electrodes 130. The studs 180 may include a metal, and may include, for example, tungsten (W), copper (Cu), or aluminum (Al).

The cell region insulating layer 190 may be disposed to cover the stack structure of the gate electrodes 130 and the contact plugs 170. The cell region insulating layer 190 may be formed of an insulating material or may be formed of a plurality of insulating layers.

A through-plug 164 and capacitor contacts 165 are disposed in the second region R2 of the memory cell region CELL, which is an outer region of the plate layer 101, and may extend to the peripheral circuit region PERI by penetrating through the cell region insulating layer 190. The through-plug 164 and the capacitor contacts 165 may be arranged to connect the studs 180 of the memory cell region CELL and the lower interconnection structure 250 of the peripheral circuit region PERI. The through-plug 164 and the capacitor contacts 165 may include a conductive material, may include, for example, a metallic material such as tungsten (W), copper (Cu), or aluminum (Al). The through-plug 164 and capacitor contacts 165 may be formed in the same process operation as the contact plugs 170, and may include the same material and may have the same internal structure.

The capacitor structure 200 may be disposed in the second region R2, and may be disposed over the peripheral circuit region PERI and the memory cell region CELL. The capacitor structure 200 may perform a function of storing electric charges.

FIG. 1E is a cross-sectional view of an example of a semiconductor device.

Referring to FIG. 1E, a semiconductor device 10d may include a first semiconductor structure S1 and a second semiconductor structure S2 bonded using a wafer bonding manner.

The description of the peripheral circuit structure PERI described above with reference to FIG. 1D may be applied to the first semiconductor structure S1. However, the first semiconductor structure S1 may further include second bonding vias 295, second bonding metal layers 298, and a second bonding insulating layer 299, which are included in a bonding structure. The second bonding vias 295 may be connected to interconnections 250b in an uppermost portion. At least a portion of the second bonding metal layer 298 may be connected to the second bonding vias 295. The second bonding metal layer 298 may be connected to the first bonding metal layers 198 of the second semiconductor structure S2. The second bonding metal layers 298 and the first bonding metal layers 198 may provide an electrical connection path for bonding the first semiconductor structure S1 and the second semiconductor structure S2. Some of the second bonding metal layers 298 may not be connected to lower interconnections 250b and may be disposed only for bonding.

The second bonding vias 295 and the second bonding metal layers 298 may include a conductive material, for example, copper (Cu). The second bonding insulating layer 299 may be disposed around the second bonding metal layers 298. The second bonding insulating layer 299 may also function as a diffusion barrier for the second bonding metal layers 298, and may include, for example, at least one of SiN, SiON, SiCN, SiOC, SiOCN, and SiO.

If there is no other explanation for the second semiconductor structure S2, the description of the memory cell structure CELL described above with reference to FIGS. 1A to 1D may be applied. The second semiconductor structure S2 may further include studs 180 and cell interconnection lines 185. The second semiconductor structure S2 may further include first bonding vias 195, first bonding metal layers 198, and first bonding insulating layer 199, which are included in the bonding structure. In an example, the second semiconductor structure S2 may further include a passivation layer 106 covering an upper surface of the plate layer 101 and an upper surface of the substrate insulating layers 121.

The studs 180 may be included in a cell interconnection structure electrically connected to the memory cells of the second semiconductor structure S2. The studs 180 may be connected to the channel structures CH and the contact plugs 170 and may be electrically connected to the channel structure CH and the gate electrodes 130. The studs 180 are illustrated in a plug shape, but the present disclosure is not limited thereto and may also have a line shape. In an example, the studs 180 may include a metal, and may include, for example, tungsten (W), copper (Cu), or aluminum (Al).

The cell interconnection lines 185 may be connected to the studs 180. However, in some implementations, the number of layers and an arrangement form of plugs and interconnection lines included the cell interconnection structure may be variously changed. The cell interconnection lines 185 may be formed of a conductive material, and may include, for example, at least one of tungsten (W), aluminum (Al), and copper (Cu).

The first bonding vias 195 and the first bonding metal layers 198 may be disposed below the cell interconnection lines 185 in the lowermost portion. The first bonding vias 195 may connect the cell interconnection lines 185 and the first bonding metal layers 198, and the first bonding metal layers 198 may be bonded to the second bonding metal layers 298 of the first semiconductor structure S1. The first bonding insulating layer 199 may be bonded and connected to the second bonding insulating layer 299 of the first semiconductor structure S1. The first bonding vias 195 and the first bonding metal layers 198 may include a conductive material, such as copper (Cu). The second bonding insulating layer 199 may include, for example, at least one of SiO, SiN, SiCN, SiOC, SiON, and SiOCN.

The first and second semiconductor structures S1 and S2 may be bonded by bonding the first bonding metal layers 198 and the second bonding metal layers 298 and bonding the first bonding insulating layer 199 and the second bonding insulating layer 299. The bonding of the first bonding metal layers 198 and the second bonding metal layers 298 may be, for example, copper (Cu)-copper (Cu) bonding, and the bonding of the first bonding insulating layer 199 and the second bonding insulating layer 299 may be, for example, dielectric-dielectric bonding such as SiCN—SiCN bonding. The first and second semiconductor structures S1 and S2 may be bonded by hybrid bonding including copper (Cu)-copper (Cu) bonding and dielectric-dielectric bonding.

The passivation layer 106 may be disposed on the upper surface of the plate layer 101 and may protect the semiconductor device 10d. The passivation layer 106 may include an insulating material, for example, at least one of silicon oxide, silicon nitride, and silicon carbide. The substrate insulating layer 121 may be widely disposed in the first region R1 and the second region R2 so as to cover an upper end of the contact plugs 170, an upper end of the through-plug 164, and an upper end of the capacitor contacts 165. However, in some implementations, an arrangement form of the substrate insulating layer 121 may be variously changed in a range in which the contact plugs 170, the through-plug 164 and the capacitor contacts 165 are electrically separated from the plate layer 101.

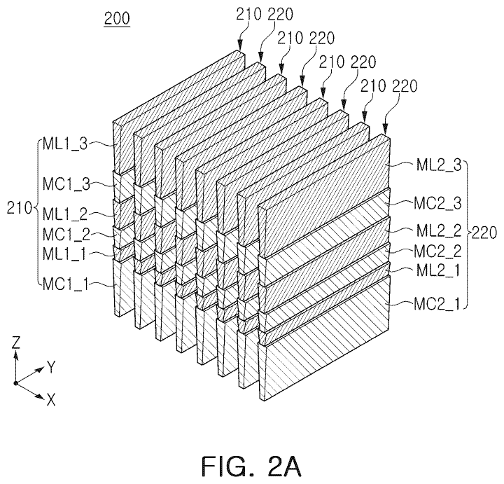

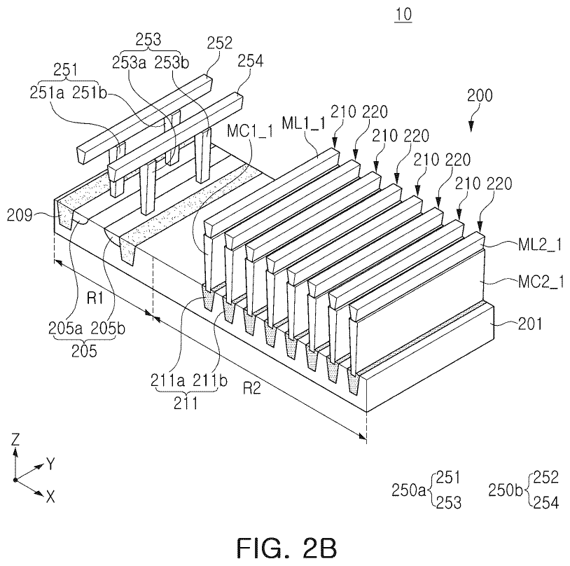

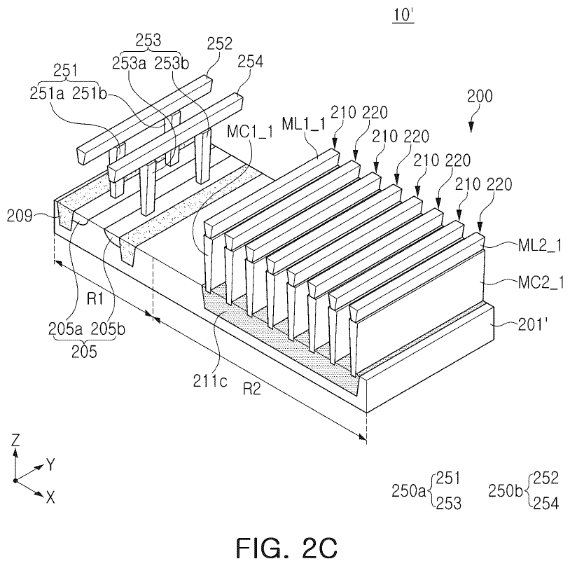

FIG. 2A is a schematic perspective view illustrating an example of a capacitor structure of a semiconductor device.

Referring to FIG. 2A, the capacitor structure 200 may include a first electrode structure 210 and a second electrode structure 220. First electrodes MC1_1, ML1_1, MC1_2, ML1_2, MC1-3 and ML1_3 included in the first electrode structure 210 and second electrodes MC2_1, ML2_1, MC2_2, ML2_2, MC2-3 and ML2_3 included in the second electrode structure 220 may be arranged alternately in the first direction (X-direction). In an example, the capacitor structure 200 may further include an insulating layer (e.g., the peripheral region insulating layer 290 in FIG. 1D) filling a space between the first electrode structure 210 and the second electrode structure 220.

The first electrode structure 210 and the second electrode structure 220 may have different electric potentials. In an example, each of the first electrode structure 210 and the second electrode structure 220 may receive an electrical signal through separate interconnections connected to each of the first electrode structure 210 and the second electrode structure 220.

Each of the first electrode structure 210 and the second electrode structure 220 may be formed by stacking a plurality of contact electrodes and a plurality of interconnection electrodes in a plate shape.

The first electrode structure 210 may include a first lower contact electrode MC1_1, a first lower interconnection electrode ML1_1, a first intermediate contact electrode MC1_2, a first intermediate interconnection electrode ML1_2, a first upper contact electrode MC1_3, and a first upper interconnection electrode ML1_3, which are sequentially stacked in the third direction (Z-direction).

As the number of contact electrodes and interconnection electrodes stacked on the first lower interconnection electrode ML1_1 increases, contact electrodes and interconnection electrodes having a relatively large height may be provided and/or formed. In an example, a height of the first intermediate contact electrode MC1-2 may be higher than a height of the first lower interconnection electrode ML1_1, and a height of the first intermediate interconnection electrode ML1_2 may be higher than a height of the first intermediate contact electrode MC1_2. A height of the first upper contact electrode MC1-3 may be higher than a height of the first intermediate interconnection electrode ML1_2, and a height of the first upper interconnection electrode ML1_3 may be higher than a height of the first upper contact electrode MC1_3. For example, the height of the first lower interconnection electrode ML1_1 may be about 1000 Å, the height of the first intermediate contact electrode MC1-2 may be about 2000 Å, the height of the first intermediate interconnection electrode ML1_2 may be about 2700 Å, and the height of the first upper contact electrode MC1-3 may be approximately 3000 Å, and the height of the first upper interconnection electrode ML1_3 may be approximately 5100 Å.

A height of the first lower contact electrode MC1-1 may be higher than a height of the first lower interconnection electrode ML1_1, the first intermediate contact electrode MC1_2, the first intermediate interconnection electrode ML1_2, and the first upper contact electrode MC1_3. For example, the height of the first lower contact electrode MC1-1 in the third direction (Z-direction) may be about 3800 Å.

The second electrode structure 220 may have substantially the same structure as the first electrode structure 210. In an example, the second electrode structure 220 may include a second lower contact electrode MC2_1, a second lower interconnection electrode ML2_1, a second intermediate contact electrode MC2_2, a second intermediate interconnection electrode ML2_2, a second upper contact electrode MC3_3, and a second upper contact interconnection ML3_3, which are sequentially stacked in the third direction (Z-direction).

Each of the first and second lower contact electrodes MC1-1 and MC2_1, the first and second lower interconnection electrodes ML1_1 and ML2_1, the first and second intermediate contact electrodes MC1-2 and MC2_2, the first and second intermediate interconnection electrodes ML1_2 and ML2_2, the first and second upper contact electrodes MC1-3 and MC2_3, and the first and second upper interconnection electrodes ML1_3 and ML2_3 may have a plate shape (or wall type) extending in the second direction (Y-direction) and a third direction (Z-direction).

Each of the first and second lower contact electrodes MC1-1 and MC2_1, the first and second lower interconnection electrodes ML1_1 and ML2_1, the first and second intermediate contact electrodes MC1-2 and MC2_2, the first and second intermediate interconnection electrodes ML1_2 and ML2_2, the first and second upper contact electrodes MC1-3 and MC2_3, and the first and second upper interconnection electrodes ML1_3 and ML2_3 may have inclined side surfaces that become narrower towards a lower portion.

Each of the first and second lower contact electrodes MC1-1 and MC2_1, the first and second lower interconnection electrodes ML1_1 and ML2_1, the first and second intermediate contact electrodes MC1-2 and MC2_2, the first and second intermediate interconnection electrodes ML1_2 and ML2_2, the first and second upper contact electrodes MC1-3 and MC2_3, and the first and second upper interconnection electrodes ML1_3 and ML2_3 may be formed by a single damascene process.

The first lower contact electrode MC1-1 is an electrode disposed in a lowermost portion of the first electrode structure 210 and may be disposed on the substrate (e.g., the substrate 201 in FIG. 1D). The first lower contact electrode MC1-1 may have a height higher than the height of the first lower interconnection electrode ML1_1 disposed on the first lower contact electrode MC1-1 in the third direction (Z-direction).

The second lower contact electrode MC2-1 is an electrode disposed in a lowermost portion of the second electrode structure 220, and may be arranged alternately with the first lower contact electrode MC1_1. The second lower contact electrode MC2-1 may have a height higher than the height of the second lower interconnection electrode ML2_1 disposed on the second lower contact electrode MC2-1 in the third direction (Z-direction).

The first electrode structure 210 and the second electrode structure 220 may include a conductive material. For example, the first electrode structure 210 and the second electrode structure 220 may include a metal such as tungsten (W), titanium (Ti), tantalum (Ta), copper (Cu), or aluminum (Al), but the present disclosure is not limited thereto.

Each of the first electrode structure 210 and the second electrode structure 220 is illustrated as including three contact electrodes and three interconnection electrodes, but the present disclosure is not limited thereto, and the number of contact electrodes and interconnection electrodes of the first electrode structure 210 and the second electrode structure 220 may be variously changed.

The semiconductor device may include a capacitor structure 200, and the capacitor structure 200 may include the first electrode structure 210 including the first lower contact electrode MC1-1 having a relatively large height in the vertical direction, and may include the second electrode structure 220 including the second lower contact electrode MC2-1 having a relatively large height in the vertical direction. Accordingly, the height of the capacitor structure 200 in the vertical direction may relatively increase, thereby providing a semiconductor device with improved electrical characteristics by securing high electrostatic capacity.

FIG. 2B is a perspective view illustrating an example of a semiconductor device including the capacitor structure of FIG. 2A.

Referring to FIG. 2B, the semiconductor device may include a capacitor structure 200 and interconnection structures 250a and 250b. The capacitor structure 200 and the interconnection structures 250a and 250b may be disposed in the peripheral circuit structure (PERI) described above with reference to FIGS. 1A to 1D. The peripheral circuit structure PERI may include a first region R1 and a second region R2 disposed in parallel with the first region R1. The interconnection structures 250a and 250b may be disposed on the first region R1, and the capacitor structure 200 may be disposed on the second region R2.

The interconnection structures 250a and 250b may include a contact plug 250a disposed on the substrate 201 and interconnections 250b on the contact plug 250a. The interconnection structures 250a and 250b may include a conductive material. For example, the interconnection structures 250a and 250b may include a metal such as tungsten (W), titanium (Ti), tantalum (Ta), copper (Cu), or aluminum (Al), but the present disclosure is not limited thereto.

The contact plug 250a may include a first contact plug 251 and a second contact plug 253 disposed on impurity regions 205. The first contact plug 251 may be disposed on a first impurity region 205a, and the second contact plug 253 may be disposed on a second impurity region 205b. In an example, a circuit element (e.g., the circuit element 230 of FIG. 1D) may be disposed between the first impurity region 205a and the second impurity region 205b. In an example, when the first impurity region 205a is a source region, the second impurity region 205b may be a drain region, and when the first impurity region 205a is a drain region, the second impurity region 205b may be a source region.

The first contact plug 251 may include a 1-1 contact plug 251a and a 1-2 contact plug 251b spaced apart from each other in the second direction (Y-direction) on the first impurity region 205a. In an example, the second contact plug 253 may include a 2-1 contact plug 253a and a 2-2 contact plug 253b spaced apart from each other in the second direction (Y-direction) on the second impurity region 205b. However, the present disclosure is not limited thereto, and the first contact plug 251 may include only one 1-1 contact plug 251a, excluding the 1-2 contact plug 251b, and the second contact plug 253 may include only the 2-1 contact plug 253a, excluding the 2-2 contact plug 253b.

The first contact plug 251 and the second contact plug 253 may have a pillar shape of which the width becomes narrower as they approach the substrate 201. For example, the first contact plug 251 and the second contact plug 253 may have the shape of a square pillar or a cylinder, but the present disclosure is not limited thereto.

The interconnections 250b may include a first peripheral interconnection 252 disposed on the first contact plug 251 and a second peripheral interconnection 254 disposed on the second contact plug 253. In an example, the first and second peripheral interconnections 252 and 254 may have a line shape extending in the second direction (Y-direction).

The capacitor structure 200 may be disposed on an insulating trench 211 in substrate 201. The insulating trench 211 may include a first finger trench 211a and a second finger trench 211b spaced apart from the first finger trench 211a.

The first finger trench 211a and the second finger trench 211b may have a shallow trench isolation (STI) structure. The first finger trench 211a and the second finger trench 211b may have substantially the same structure. In an example, the first finger trench 211a and the second finger trench 211b may have a structure in which a width thereof becomes narrower toward the lower surface of the substrate 201. The first finger trench 211a may be regions in which electrodes disposed in a lowermost portion of the first electrode structure 210 of the capacitor structure 200 are disposed. The second finger trench 211b may be regions in which electrodes disposed a lowermost portion of the second electrode structure 220 of the capacitor structure 200 are disposed.

The first finger trench 211a and the second finger trench 211b may include an insulating material filling a trench structure. For example, the insulating material may be fluoride silicate glass (FSG), undoped silicate glass (USG), boro-phospho-silicate glass (BPSG), phospho-silicate glass (PSG), flowable oxide (FOX), and plasma enhanced tetra-ethyl-ortho-silicate (PE-TEOS), or tonen silazene (TOSZ), but the present disclosure is not limited thereto.

The first electrode structure 210 may be disposed on the first finger trench 211a, and the second electrode structure 220 may be disposed on the second finger trench 211b. The first finger trenches 211a and the second finger trenches 211b may be alternately arranged at regular intervals in the first direction (X-direction). In an example, the first finger trench 211a and the second finger trench 211b may extend in a second direction (Y-direction), which is an extension direction of the first electrode structure 210 and the second electrode structure 220. In an example, a gap between the first finger trench 211a and the second finger trench 211b may be substantially equal to a gap between the first electrode structure 210 and the second electrode structure 220.

The first lower contact electrode MC1-1 and the first lower interconnection electrode ML1_1 may be sequentially stacked on the first finger trench 211a. In the drawing, only the first lower contact electrode MC1-1 and the first lower interconnection electrode ML1_1 are illustrated as electrodes of the first electrode structure 210, but the first intermediate contact electrode MC1_2, the first intermediate interconnection electrode ML1_2, the first upper contact electrode MC1-3 and the first upper interconnection electrode ML1_3 may be sequentially stacked on the first lower interconnection electrode ML1_1.

The second lower contact electrode MC2-1 and the second lower interconnection electrode ML2_1 may be sequentially stacked on the second finger trench 211b. In the drawing, only the second lower contact electrode MC2-1 and the second lower interconnection electrode ML2_1 are illustrated as electrodes of the second electrode structure 220, but the second intermediate contact electrode MC2_2, the second intermediate interconnection electrode ML2_2, the second upper contact electrode MC3_3, the second upper contact interconnection ML3_3 may be sequentially stacked on the second lower interconnection electrode ML2_1.

The first lower contact electrode MC1-1 may penetrate through a portion of the first finger trench 211a. A lower surface of the first lower contact electrode MC1-1 may penetrate through an upper surface of the first finger trench 211a and may be buried in the first finger trench 211a. The lower surface of the first lower contact electrode MC1-1 may be disposed on a level lower than that of the upper surface of the first finger trench 211a, and may be disposed on a level higher than that of a lower surface of the first finger trench 211a.

The second lower contact electrode MC2-1 may penetrate through a portion of the second finger trench 211b. A lower surface of the second lower contact electrode MC2-1 may penetrate through an upper surface of the second finger trench 211b and may be buried in the second finger trench 211b. The lower surface of the second lower contact electrode MC2-1 may be disposed on a level lower than that of the upper surface of the second finger trench 211b, and may be disposed on a level higher than that of a lower surface of the second finger trench 211b.

In some implementations, the lower surface of the first lower contact electrode MC1-1 may be disposed on the same level as the upper surface of the first finger trench 211a. The lower surface of the second lower contact electrode MC2-1 may be disposed on the same level as the upper surface of the second finger trench 211b.

The first finger trench 211a and the second finger trench 211b may be provided and/or formed in the same process as the element isolation region 209. In an example, the upper surface of the first finger trench 211a and the upper surface of the second finger trench 211b may be disposed on the same level as the upper surface of the element isolation region 209. In an example, the lower surface of the first finger trench 211a and the lower surface of the second finger trench 211b may be disposed on the same level as a lower surface of the element isolation region 209. However, the present disclosure is not limited thereto. The lower surfaces of the first and second finger trenches 211a and 211b may be disposed on a level lower than that of the lower surface of the element isolation region 209. In another example, the lower surfaces of the first and second finger trenches 211a and 211b may be disposed on a level higher than that of the lower surface of the element isolation region 209. In some implementations, the first finger trench 211a and the second finger trench 211b may have the same shape as the element isolation region 209, but the present disclosure is not limited thereto.

The number of first finger trenches 211a may correspond to the number of first lower contact electrodes MC1_1, which are lowermost electrodes of the first electrode structure 210, and the number of second finger trenches 211b may correspond to the number of second lower contact electrodes MC2_1, which are lowermost electrodes of the second electrode structure 220.

The first lower contact electrode MC1-1 and the second lower contact electrode MC2-1 may be provided and/or formed in the same process as the first and second contact plugs 251 and 253. In an example, the upper surfaces of the first and second contact plugs 251 and 253 may be disposed on the same level as the upper surfaces of the first and second lower contact electrodes MC1-1 and MC2_1.

The first lower interconnection electrode ML1_1 and the second lower interconnection electrode ML2_1 may be provided and/or formed in the same process as the first and second peripheral interconnections 252 and 254. In an example, the upper surface of the first lower interconnection electrode ML1_1 and the upper surface of the second lower interconnection electrode ML2_1 may be disposed on the same level as the upper surface of the first and second peripheral interconnections 252 and 254.

FIG. 2C is a perspective view illustrating another example of a semiconductor device including the capacitor structure of FIG. 2A.

Referring to FIG. 2C, the remaining components except for an insulating trench 211c in a substrate 201′ may be identical to or similar to those illustrated in FIG. 2B.

A semiconductor device 10′ may include the substrate 201′, the insulating trench 211c in the substrate 201′ and a capacitor structure 200 on the insulating trench 211c.

The insulating trench 211c may be provided integrally with a front surface of a region in which the capacitor structure 200 is disposed in the substrate 201′.

The insulating trench 211c may have an inclined side surface of which the width becomes narrower toward the lower surface of the substrate 201. The insulating trench 211c may include an insulating material filling the trench structure. In an example, a width of the insulating trench 211c in the first direction (X-direction) may be greater than a width of the capacitor structure 200 in the first direction (X-direction).

The first electrode structure 210 and the second electrode structure 220 may be disposed on the insulating trench 211c. In an example, the first lower contact electrode MC1-1 and the second lower contact electrode MC2-1 may penetrate through a portion of the insulating trench 211c. A lower surface of the first lower contact electrode MC1-1 and a lower surface of the second lower contact electrode MC2-1 may penetrate through an upper surface of the insulating trench 211c and may be buried in the insulating trench 211c. The lower surface of the first lower contact electrode MC1-1 and the lower surface of the second lower contact electrode MC2-1 may be disposed on a level lower than that of the upper surface of the insulating trench 211c, and may be disposed on a level higher than that of a lower surface of the insulation trench 211c. In some implementations, the lower surface of the first lower contact electrode MC1-1 and the lower surface of the second lower contact electrode MC2-1 may be disposed on the same level as the upper surface of the insulating trench 211c.

The insulating trench 211c may include an insulating material filling the trench structure.

The insulating trench 211c may be provided and/or formed in the same process as the element isolation region 209. The lower surface of the insulation trench 211c may be disposed on the same level as the lower surface of the element isolation region 209. In an example, the width of the insulating trench 211c in the first direction (X-direction) may be larger than a width of the element isolation region 209 in the first direction (X-direction). The lower surface of the insulation trench 211c may be disposed on the same level as the lower surface of the element isolation region 209.

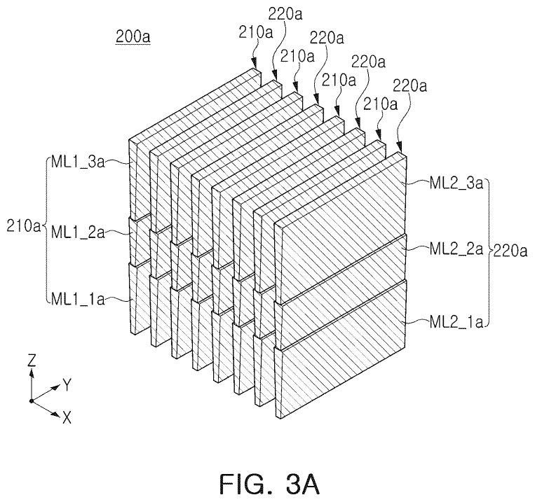

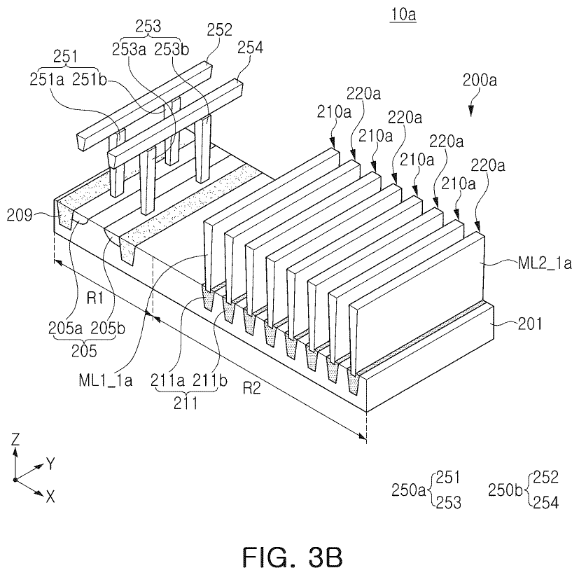

FIG. 3A is a schematic perspective view illustrating another example of a capacitor structure of a semiconductor device.

Referring to FIG. 3A, a capacitor structure 200a may include a first electrode structure 210a and a second electrode structure 220a. First electrodes ML1_1a, ML1_2a and ML1_3a included in the first electrode structure 210a and second electrodes ML2_1a, ML2_2a and ML2_3a included in the second electrode structure 220a may be arranged alternately in the first direction (X-direction). In an example, the capacitor structure 200a may further include an insulating layer (e.g., the peripheral region insulating layer 290 in FIG. 1D) filling a space between the first electrode structure 210a and the second electrode structure 220a.

The first electrode structure 210a and the second electrode structure 220a may be formed by stacking a plurality of interconnection electrodes having a plate shape.

The first electrode structure 210a may include a first lower interconnection electrode ML1_1a, a first intermediate interconnection electrode ML1_2a, and a first upper interconnection electrode ML1_3a, which are sequentially stacked in the third direction (Z-direction).

A height of the first lower interconnection electrode ML1_1a in the third direction (Z-direction) is higher than a height of the first intermediate interconnection electrode ML1_2a, and may be lower than a height of the first upper interconnection electrode ML1_3a. However, the present disclosure is not limited thereto, and in another example, the height of the first lower interconnection electrode ML1_1a may be lower than the height of the first intermediate interconnection electrode ML1_2a.

The second electrode structure 220b may include a second lower interconnection electrode ML2_1a, a second intermediate interconnection electrode ML2_2a, and a second upper interconnection electrode ML2_3a, which are sequentially stacked in the third direction (Z-direction).

A height of the second lower interconnection electrode ML2_1a in the third direction (Z-direction) may be higher than a height of the second intermediate interconnection electrode ML2_2a, and may be lower than a height of the second upper interconnection electrode ML2_3a. However, the present disclosure is not limited thereto, and in another example, the height of the second lower interconnection electrode ML2_1a may be lower than the height of the second intermediate interconnection electrode ML2_2a.

Each of the first and second lower interconnection electrodes ML1_1a and ML2_1a, the first and second intermediate interconnection electrodes ML1_2a and ML2_2a, and the first and second upper interconnection electrodes ML1_3a and ML2_3a may have a plate shape (or wall type) extending in the second direction (Y-direction) and the third direction (Z-direction).

Lengths of the first and second lower interconnection electrodes ML1_1a and ML2_1a, the first and second intermediate interconnection electrodes ML1_2a and ML2_2a, and the first and second upper interconnection electrodes ML1_3a and ML2_3a in the second direction Y-direction) may be substantially identical to each other.

Each of the first and second lower interconnection electrodes ML1_1a and ML2_1a, the first and second intermediate interconnection electrodes ML1_2a and ML2_2a, and the first and second upper interconnection electrodes ML1_3a and ML2_3a may have inclined side surfaces that become narrower towards a lower portion.

Interconnection electrodes of each of the first and second lower interconnection electrodes ML1_1a and ML2_1a, the first and second intermediate interconnection electrodes ML1_2a and ML2_2a, and the first and second upper interconnection electrodes ML1_3a and ML2_3a may be formed in a dual damascene process.

The first lower interconnection electrode ML1_1a is an electrode disposed in a lowermost portion of the first electrode structure 210a and may be disposed on a substrate (e.g., the substrate 201 in FIG. 1D).

The second lower interconnection electrode ML2_1a is an electrode disposed in a lowermost portion of the second electrode structure 220b, and may be arranged alternately with the first lower interconnection electrode ML1_1a in the first direction (X-direction).

Each of the first electrode structure 210a and the second electrode structure 220a is illustrated as including three interconnection electrodes, but the present disclosure is not limited thereto, and the number of interconnection electrodes included in each of the first electrode structure 210a and the second electrode structure 220a may be variously changed.

The semiconductor device may include the capacitor structure 200a, and the capacitor structure 200a may include the first electrode structure 210a including the first lower interconnection electrode ML1_1a and the second electrode structure 220a including the second lower interconnection electrode ML2_1a.

FIG. 3B is a perspective view illustrating an example of a semiconductor device including the capacitor structure of FIG. 3A.

Referring to FIG. 3B, a semiconductor device 10a may include a capacitor structure 200a and interconnection structures 250a and 250b.

The capacitor structure 200a may be disposed on an insulating trench 211 in a substrate 201. The first electrode structure 210a may be disposed on the first finger trench 211a, and the second electrode structure 220a may be disposed on the second finger trench 211b.

In some implementations, the capacitor structure 200a may be provided on an insulating trench (e.g., the insulating trench 211c in FIG. 2C) integrally formed on a front surface of a region in which the capacitor structure 200a is disposed in the substrate 201.

A first lower interconnection electrode ML1_1a may be disposed on the first finger trench 211a. In the drawing, only the first lower interconnection electrode ML1_1a is illustrated as an electrode of the first electrode structure 210a disposed on the first finger trench 211a, but a first intermediate interconnection electrode ML1_2a and a first upper interconnection electrode ML1_3a may be sequentially stacked on the first lower interconnection electrode ML1_1a.

A second lower interconnection electrode ML2_1a may be disposed on the second finger trench 211b. In the drawing, only the second lower interconnection electrode ML2_1a is illustrated as an electrode of the second electrode structure 220b disposed on the second finger trench 211b, but a second intermediate interconnection electrode ML2_2a and a second upper interconnection electrode ML2_3a may be sequentially stacked on the second lower interconnection electrode ML2_1a.

The first lower interconnection electrode ML1_1a may penetrate through a portion of the first finger trench 211a. A lower surface of the first lower interconnection electrode ML1_1a may penetrate through the upper surface of the first finger trench 211a and may be buried in the first finger trench 211a. The lower surface of the first lower interconnection electrode ML1_1a may be disposed on a level lower than that of the upper surface of the first finger trench 211a, and may be disposed on a level higher than that of the lower surface of the first finger trench 211a.

The second lower interconnection electrode ML2_1a may penetrate through a portion of the second finger trench 211b. A lower surface of the second lower interconnection electrode ML2_1a may penetrate through the upper surface of the second finger trench 211b and may be buried in the second finger trench 211b. The lower surface of the second lower interconnection electrode ML2_1a may be disposed on a level lower than that of the upper surface of the second finger trench 211b, and may be disposed on a level higher than that of the lower surface of the second finger trench 211b.

In some implementations, the first lower interconnection electrode ML1_1a may be disposed on the same level as the upper surface of the first finger trench 211a. The second lower interconnection electrode ML2_1a may be disposed on the same level as the upper surface of the second finger trench 211b.

The first lower interconnection electrode ML1_1a and the second lower interconnection electrode ML2_1a may be provided and/or formed in the same process as the first and second contact plugs 251 and 253. In an example, the upper surfaces of the first and second contact plugs 251 and 253 may be disposed on the same level as the upper surface of the first lower interconnection electrode ML1_1a and the upper surface of the second lower interconnection electrode ML2_1a.

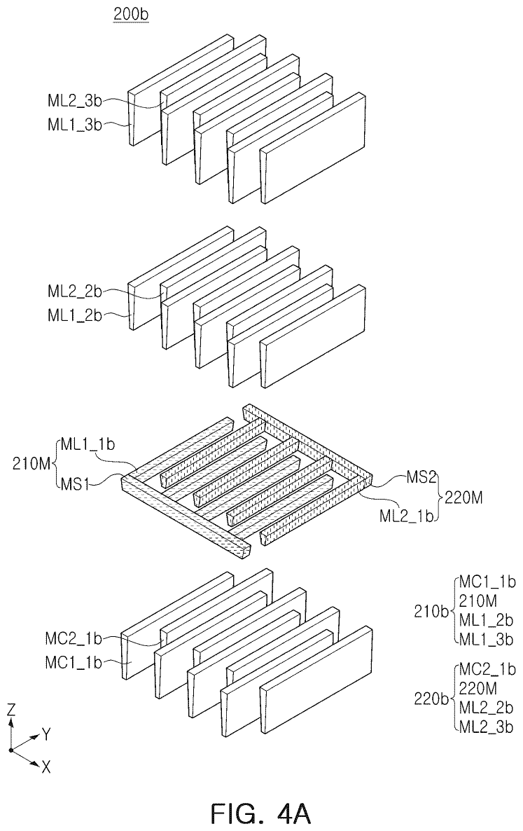

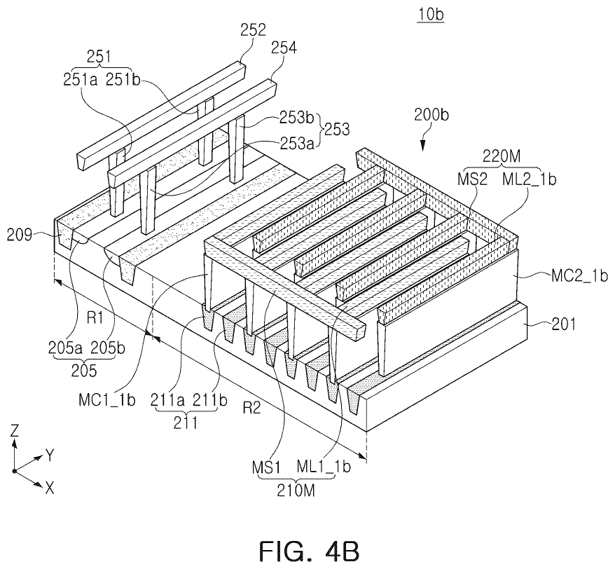

FIG. 4A is a schematic perspective view illustrating another example of a capacitor structure of a semiconductor device.

Referring to FIG. 4A, a capacitor structure 200b may include a first electrode structure 210b and a second electrode structure 220b. In an example, first electrodes MC1_1b, ML1_1b, ML1_2b and ML1_3b included in the first electrode structure 210b may be arranged alternately in the first direction (X-direction) with second electrodes MC2_1b, ML2_1b, ML2_2b and ML2_3b included in the second electrode structure 220b.

The first electrode structure 210b may include a first lower contact electrode MC1_1b, a first intermediate electrode structure 210M, a first intermediate interconnection electrode ML1_2b, and a first upper interconnection electrode ML1_3b, which are sequentially stacked in the third direction (Z-direction).

The first intermediate electrode structure 210M may include a first connection portion MS1 extending in the first direction (X-direction) and first intermediate electrodes ML1_1b protruding and extending from the first connection portion MS1 in the second direction (Y-direction). The first connection portion MS1 may electrically connect the first intermediate electrodes ML1_1b. In an example, a height of the first connection portion MS1 in the third direction (Z-direction) may be substantially equal to a height of the first intermediate electrode ML1_1b in the third direction (Z-direction).

A height of the first lower contact electrode MC1_1b in the third direction (Z-direction) may be higher than a height of the first intermediate electrode structure 210M.

The second electrode structure 220b may include a second lower contact electrode MC2_1b, a second intermediate electrode structure 220M, a second intermediate interconnection electrode ML2_2b, and a second upper interconnection electrode ML2_3b, which are sequentially stacked in the third direction (Z-direction).

The second intermediate electrode structure 220M may include a second connection portion MS2 extending in the first direction (X-direction), and second intermediate electrodes ML2_1b protruding and extending from the second connection portion MS2 in the second direction (Y-direction) and arranged alternately with the first intermediate electrode ML1_1b in the first direction (X-direction). The second connection portion MS2 may electrically connect the second intermediate electrodes ML2_1b. In an example, a height of the second connection portion MS2 in the third direction (Z-direction) may be substantially equal to a height of the second intermediate electrode ML2_1b in the third direction (Z-direction).

The first and second strap portions MS1 and MS2 and the first and second intermediate electrodes ML1_1b and ML2_1b may be provided and/or formed in the same process. The first and second strap portions MS1 and MS2 and the first and second intermediate electrodes ML1_1b and ML2_1b may include the same material.

The first connection portion MS1 and the second connection portion MS2 may be spaced apart from each other in the second direction (Y-direction).

A length of the first and second lower contact electrodes MC1_1b and MC2_1b in the second direction (Y-direction) may be substantially equal to a length of the first and second intermediate electrode structures 210M and 220M in the second direction (Y-direction).

The first and second lower contact electrodes MC1_1b and MC2_1b, the first and second intermediate electrode structures 210M and 220M, the first and second intermediate interconnection electrodes ML1_2b and ML2_2b, and the first and second upper interconnection electrodes ML1_3b and ML2_3b may have a plate shape extending in the second direction (Y-direction) and the third direction (Z-direction).

Each of the first and second lower contact electrodes ML1_1b and ML2_1b and the first and second intermediate electrode structures 210M and 220M may be formed in a single damascene process.

The first intermediate interconnection electrode ML1_2b and the first upper interconnection electrode ML1_3b may be sequentially stacked on the first intermediate electrodes ML1_1b of the first intermediate electrode structure 210M. The second intermediate interconnection electrode ML2_2b and the second upper interconnection electrode ML2_3b may be disposed on the second intermediate electrodes ML2_1b of the second intermediate electrode structure 220M. In an example, a height of the first and second upper interconnection electrodes ML1_3b and ML2_3b in the third direction (Z-direction may be greater than a height of the first and second intermediate interconnection electrodes ML1_2b and ML2_2b.

The first lower contact electrode MC1_1b is an electrode disposed in a lowermost portion of the first electrode structure 210b and may be disposed on a substrate (e.g., the substrate 201 in FIG. 1D). The first lower contact electrode MC1_1b may have a height greater than the height of the first intermediate electrode structure 210M disposed on the first lower contact electrode MC1_1b in the third direction (Z-direction).

The second lower contact electrode MC2_1b is an electrode disposed in a lowermost portion of the second electrode structure 220b and may be arranged alternately with the first lower contact electrode MC1_1b. The second lower contact electrode MC2_1b may have a height higher than a height of the second intermediate electrode structure 220M disposed on the second lower contact electrode MC2_1b in the third direction (Z-direction).

FIG. 4B is a perspective view illustrating an example of a semiconductor device including the capacitor structure of FIG. 4A.

Referring to FIG. 4B, a semiconductor device 10b may include a capacitor structure 200b and interconnection structures 250a and 250b.

The capacitor structure 200b may be disposed on first and second finger trenches 211a and 211b in a substrate 201. The first electrode structure 210b may be disposed on the first finger trench 211a, and the second electrode structure 220b may be disposed on the second finger trench 211b.

In some implementations, the capacitor structure 200b may be provided on an insulating trench (e.g., the insulating trench 211c in FIG. 2C) integrally formed on a front surface of a region in which the capacitor structure 200b is disposed in the substrate 201.

A first lower contact electrode MC1_1b and a first intermediate electrode structure 210M may be sequentially stacked on the first finger trench 211a. In the drawing, only the first lower contact electrode MC1_1b and the first intermediate electrode structure 210M are illustrated as electrodes of the first electrode structure 210b on the first finger trench 211a, but a first intermediate interconnection electrode ML1_2b and a first upper interconnection electrode ML1_3b may be sequentially stacked on the first intermediate electrode structure 210M.

A second lower contact electrode MC2_1b and a second intermediate electrode structure 220M may be sequentially stacked on the second finger trench 211b. In the drawing, only the second lower contact electrode MC2_1b and the second intermediate electrode structure 220M are illustrated as electrodes of the second electrode structure 220b on the second finger trench 211b, but a second intermediate interconnection electrode ML2_2b and a second upper interconnection electrode ML2_3b may be sequentially stacked on the second intermediate electrode structure 220M.

The first lower contact electrode MC1_1b may penetrate through a portion of the first finger trench 211a. A lower surface of the first lower contact electrode MC1_1b may penetrate through an upper surface of the first finger trench 211a and may be buried in the first finger trench 211a. The lower surface of the first lower contact electrode MC1_1b may be disposed on a level lower than that of an upper surface of the first finger trench 211a, and may be disposed on a level higher than that of a lower surface of the first finger trench 211a.

The second lower contact electrode MC2_1b may penetrate through a portion of the second finger trench 211b. A lower surface of the second lower contact electrode MC2_1b may penetrate through an upper surface of the second finger trench 211b and may be buried in the second finger trench 211b. The lower surface of the second lower contact electrode MC2_1b may be disposed on a level lower than that of the upper surface of the second finger trench 211b, and may be disposed on a level higher than that of a lower surface of the second finger trench 211b.

In some implementations, the first lower contact electrode MC1_1b may be disposed on the same level as the upper surface of the first finger trench 211a. The second lower contact electrode MC2_1b may be disposed on the same level as the upper surface of the second finger trench 211b.

The first lower contact electrode MC1_1b and the second lower contact electrode MC2_1b may be provided and/or formed in the same process as first and second contact plugs 251 and 253. In an example, upper surfaces of the first and second contact plugs 251 and 253 may be disposed on the same level as an upper surface of the first lower contact electrode MC1_1b and an upper surface of the second lower contact electrode MC2_1b.

The first and second intermediate electrode structures 210M and 220M may be provided and/or formed in the same process as first and second peripheral interconnections 252 and 254. In an example, upper surfaces of the first and second peripheral interconnections 252 and 254 may be disposed on the same level as upper surfaces of the first and second intermediate electrode structures 210M and 220M.

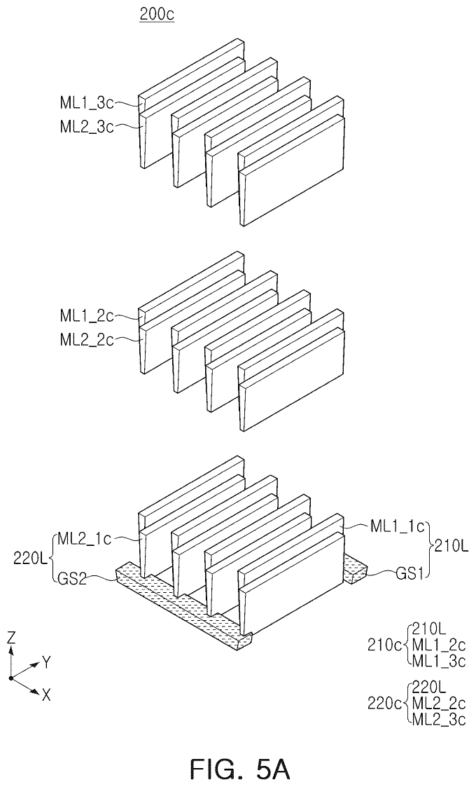

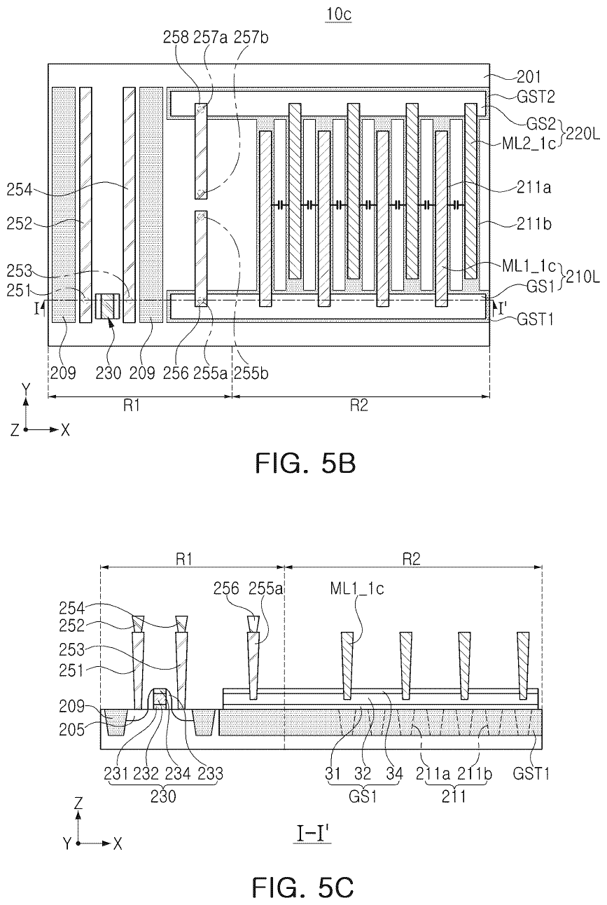

FIG. 5A is a schematic perspective view illustrating another example of a capacitor structure of a semiconductor device.

Referring to FIG. 5A, a capacitor structure 200c may include a first electrode structure 210c and a second electrode structure 220c. In an example, first electrodes ML1_1c, ML1_2c and ML1_3c included in the first electrode structure 210c and second electrodes ML2_1c, ML2_2C and ML2_3c included in the second electrode structure 220c may be arranged alternately in the first direction (X-direction). In an example, the capacitor structure 200c may further include an insulating layer (e.g., the peripheral region insulating layer 290 in FIG. 1D) filling a space between the first electrode structure 210c and the second electrode structure 220c.

The first electrode structure 210c and the second electrode structure 220c may have different electric potentials. Each of the first electrode structure 210c and the second electrode structure 220c may receive an electrical signal through separate interconnections connected to each of the first electrode structure 210c and the second electrode structure 220c.

Each of the first electrode structure 210c and the second electrode structure 220c may be provided and/or formed by stacking a plurality of interconnection electrodes having a plate shape.

The first electrode structure 210c may include a first lower electrode structure 210L, a first intermediate interconnection electrode ML1_2c, and a first upper interconnection electrode ML1_3c, which are sequentially stacked in the third direction (Z-direction).

The second electrode structure 220c may include a second lower electrode structure 220L, a second intermediate interconnection electrode ML2_2c, and a second upper interconnection electrode ML2_3c, which are sequentially stacked in the third direction (Z-direction).

The first lower electrode structure 210L may include a first strap portion GS1 extending in the first direction (X-direction) and first lower electrodes ML1_1c protruding and extending from the first strap portion GS1 in the second direction (Y-direction).

The first lower electrodes ML1_1c may extend from an upper surface of the first strap portion GS1 in the third direction (Z-direction). The first lower electrodes ML1_1c may have a plate shape extending in the second direction (Y-direction) and the third direction (Z-direction).

A portion of a lower surface of the first lower electrodes ML1_1c may penetrate through the upper surface of the first strap portion GS1 and may be buried in the first strap portion GS1. The lower surface of the first lower electrodes ML1_1c may be disposed on a level higher than that of a lower surface of the first strap portion GS1, and may be disposed on a level lower than the upper surface of the first strap portion GS1. The upper surface of the first lower electrodes ML1_1c may be disposed on a level higher than that of the upper surface of the first strap portion GS1.

The first intermediate interconnection electrodes ML1_2c and the first upper interconnection electrodes ML1_3c may overlap the first lower electrodes ML1_1c in the third direction (Z-direction).

The second lower electrode structure 220L may include a second strap portion GS2 extending in the first direction (X-direction) and second lower electrodes ML2_1c protruding and extending from the second strap portion GS2 in the second direction (Y-direction). The second lower electrodes ML2_1c may be arranged alternately with the first lower electrodes ML1_1c in the first direction (X-direction). In an example, the second strap portion GS2 may be spaced apart from the first strap portion GS1 in the second direction (Y-direction).

A separation distance between the first and second strap portions GS1 and GS2 in the second direction (Y-direction) may be substantially equal to a width of the first lower electrodes ML1_1c in the second direction (Y-direction) and a width of the second lower electrodes ML2_1c in the second direction (Y-direction). However, the present disclosure is not limited thereto, and the separation distance between the first and second strap portions GS1 and GS2 in the second direction (Y-direction) may be greater than the width of the first lower electrodes ML1_1c in the second direction (Y-direction) and the width of the second lower electrodes ML2_1c in the second direction (Y-direction).

A portion of a lower surface of the second lower electrodes ML2_1c may penetrate an upper surface of the second strap portion GS2 and may be buried in the second strap portion GS2. A lower surface of the second lower electrodes ML1_2c may be disposed on a level higher than that of a lower surface of the second strap portion GS2, and may be disposed on a level lower than the upper surface of the second strap portion GS2. An upper surface of the second lower electrodes ML1_2c may be disposed on a level higher than that of the upper surface of the second strap portion GS2.

The second intermediate interconnection electrodes ML2_2c and the second upper interconnection electrodes ML2_3c may overlap the second lower electrodes ML2_1c in the third direction (Z-direction). In an example, the second intermediate interconnection electrodes ML2_2c may be arranged alternately with the first intermediate interconnection electrodes ML1_2c in the first direction (X-direction). The second upper interconnection electrodes ML2_3c may be disposed alternately with the first upper interconnection electrodes ML1_3c arranged in the first direction (X-direction).

The first and second intermediate interconnection electrodes ML1_2c and ML2_2c and the first and second upper interconnection electrodes ML1_3c and ML2_3c may have a plate shape extending in the second direction (Y-direction) and the third direction (Z-direction).

FIG. 5B is a plan view illustrating an example of a semiconductor device including the capacitor structure of FIG. 5A. FIG. 5C is a cross-sectional view illustrating an example taken along line I-I′ of the semiconductor device of FIG. 5B.

Referring to FIGS. 5B and 5C, a semiconductor device 10c may include a capacitor structure 200c, first and second peripheral interconnections 252 and 254, third and fourth peripheral interconnections 256 and 258, and a circuit element 230.

The capacitor structure 200c, the first and second peripheral interconnections 252 and 254, the third and fourth peripheral interconnections 256 and 258, and the circuit element 230 may be disposed in the peripheral circuit structure PERI as described above with reference to FIGS. 1A to 1D.

An element isolation region 209, the first and second peripheral interconnections 252 and 254, the third and fourth peripheral interconnections 256 and 258 and the circuit element 230 may be disposed in a first region R1 of the peripheral circuit structure PERI. First and second finger trenches 211a and 211b, first and second strap trenches GST1 and GST2, and the capacitor structure 200c may be disposed in a second region R2 of the peripheral circuit structure PERI.

The element isolation region 209 and impurity regions 205 may be disposed in a substrate 201 in the first region R1, and the first and second strap trenches GST1 and GST2 and the first and second finger trenches 211a and 211b in the substrate 201 may be disposed in the second region R2.

The element isolation region 209 may define an active region inside the substrate 201. The circuit element 230 may be disposed on the substrate 201 between the element isolation regions 209. The first and second peripheral interconnections 252 and 254 may be disposed on the substrate 201 on both sides of the circuit element 230. The first and second peripheral interconnections 252 and 254 may extend in the second direction (Y-direction).

The impurity regions 205 may be disposed as source/drain regions in the substrate 201 on both sides of the circuit element 230. The first peripheral interconnection 252 may be connected to the impurity region 205 through a first contact plug 251 disposed in a lower portion of the first peripheral interconnection 252. The second peripheral interconnection 254 may be connected to the impurity region 205 through a second contact plug 253 disposed in a lower portion of the second peripheral interconnection 254.

A height of the first and second contact plugs 251 and 253 in the third direction (Z-direction) may be higher than a height of the first and second peripheral interconnections 252 and 254 in the third direction (Z-direction).

The circuit element 230 may include a peripheral gate dielectric layer 231 disposed on the substrate 201, a peripheral gate electrode 232 disposed on the peripheral gate dielectric layer 231, a peripheral gate capping layer 234 on the peripheral gate electrode 232, and a peripheral gate dielectric layer 231, a peripheral gate electrode 232, and a peripheral gate spacer 233 disposed on a sidewall of the peripheral gate capping layer 234.

The peripheral gate dielectric layer 231 may include silicon oxide (SiO₂), SiON, GeON, or GeSiO. The peripheral gate electrode 232 may include a metallic material, for example, tungsten (W). According to some implementations, the peripheral gate electrode 232 may include polycrystalline silicon or a metal silicide material. The peripheral gate capping layer 234 may include an insulating material, such as silicon nitride. The peripheral gate spacer 233 may be formed of an oxide film, a nitride film, an oxynitride film, or a combination thereof. In some implementations, the peripheral gate capping layer 234 may be omitted.

The circuit element 230 and the impurity region 205 which is a source/drain region may form a peripheral transistor. The circuit element 230 may be referred to as a gate structure in this document.

The element isolation region 209 may extend in the second direction (Y-direction). The first and second strap trenches GST1 and GST2 may be spaced apart from the element isolation region 209 in the first direction (X-direction), and may extend in the first direction (X-direction). In an example, the first and second strap trenches GST1 and GST2 may be spaced apart from each other in the second direction (Y-direction). The first and second finger trenches 211a and 211b may extend between the first and second strap trenches GST1 and GST2 in a second direction (Y-direction). The first and second finger trenches 211a and 211b may connect the first and second strap trenches GST1 and GST2.

The element isolation region 209, the first and second finger trenches 211a and 211b, and the first and second strap trenches GST1 and GST2 may include an insulating material filling the trench structure.

The first lower electrode structure 210L may be disposed on the first finger trenches 211a and the first strap trench GST1. In an example, first lower electrodes ML1_1c may be disposed on the first finger trenches 211a, and a first strap portion GS1 may be disposed on the first strap trench GST1.

A second lower electrode structure 220L may be disposed on the second finger trenches 211b and the second strap trench GST2. In an example, second lower electrodes ML2_1c may be disposed on the second finger trenches 211b, and a second strap portion GS2 may be disposed on the second strap trench GST2.

A height of the first and second strap portions GS1 and GS2 in the vertical direction (Z-direction) may be lower than a height of the first and second lower electrodes ML1_1c and ML2_1c in the vertical direction (Z-direction).

The first and second strap portions GS1 and GS2 may have the shape of a strap extending in the first direction (X-direction). In an example, the first and second strap portions GS1 and GS2 may include an insulating layer 31, a conductive layer 32 on the insulating layer 31, and a capping layer 34 on the conductive layer 32. The insulating layer 31, the conductive layer 32 and the capping layer 34 may extend in the first direction (X-direction).

A portion of a lower surface of the first lower electrodes ML1_1c may penetrate through an upper surface of the first strap portion GS1 and may be connected to a conductive layer 32 of the first strap portion GS1. The first strap portion GS1 may connect the first lower electrodes ML1_1c.

A portion of a lower surface of the second lower electrodes ML2_1c may penetrate through an upper surface of the second strap portion GS2 and may be connected to a conductive layer 32 of the second strap portion GS2. The second strap portion GS2 may connect the second lower electrodes ML2_1c.

The first and second lower electrodes ML1_1c and ML2_1c may include a first conductive material, and the first and second strap portions GS1 and GS2 may include a second conductive material different from the first conductive material. For example, the first conductive material may include copper (Cu), and the second conductive material may include a conductive material other than copper (Cu). However, the present disclosure is not limited thereto, and the first and second lower electrodes ML1_1c and ML2_1c may include the same conductive material as the first and second strap portions GS1 and GS2.

The upper surface of the first and second strap portions GS1 and GS2 may be disposed on the same level as an upper surface of the circuit element 230. In an example, an upper surface of the capping layer 34 of the first and second strap portions GS1 and GS2 may be disposed on the same level as an upper surface of the peripheral gate capping layer 234 of the circuit element 230. An upper surface of the conductive layer 32 of the first and second strap portions GS1 and GS2 may be disposed on the same level as an upper surface of the peripheral gate electrode 232 of the circuit element 230. An upper surface of the insulating layer 31 of the first and second strap portions GS1 and GS2 may be disposed on the same level as an upper surface of the peripheral gate dielectric layer 231 of the circuit element 230.

The first and second strap portions GS1 and GS2 may be provided and/or formed in the same process as the circuit element 230. In an example, the insulating layer 31 of the first and second strap portions GS1 and GS2 may include the same material as the peripheral gate dielectric layer 231 of the circuit element 230. The conductive layer 32 of the first and second strap portions GS1 and GS2 may include the same material as the peripheral gate electrode 232 of the circuit element 230. In an example, the capping layer 34 of the first and second strap portions GS1 and GS2 may include the same material as the peripheral gate capping layer 234 of the circuit element 230. However, the present disclosure is not limited thereto. In an example, the first and second strap portions GS1 and GS2 may be formed in a process different from that of the circuit element 230, and the first and second strap portions GS1 and GS2 may include a material different from that of the circuit element 230.

The first and second strap portions GS1 and GS2 may extend from the second region R2 to the first region R1. For example, the first and second strap portions GS1 and GS2 may extend to an area adjacent to the circuit element 230.

A third contact plug 255, a fourth contact plug 257, a third peripheral interconnection 256 disposed on the third contact plug 255, and a fourth interconnection peripheral interconnection 258 disposed on the fourth contact plug 257 may be disposed on the first and second strap portions GS1 and GS2 extending toward the first region R1. In an example, a third-first contact plug 255a may be disposed on the first strap portion GS1 extending toward the first region R1. A fourth-first contact plug 257a may be disposed on the second strap portion GS2 extending toward the first region R1. A third peripheral interconnection 256 may be disposed on the third-first contact plug 255a. A fourth peripheral interconnection 258 may be disposed on the fourth-first contact plug 257a.

The first lower electrodes ML1_1c may be electrically connected to the circuit element 230 through the third-first contact plug 255a and the third peripheral interconnection 256. That is, a first signal may be applied to the first lower electrodes ML1_1c through the third-first contact plug 255a and the third peripheral interconnection 256.

The second lower electrodes ML2_1c may be electrically connected to the circuit element 230 through the fourth-first contact plug 257a and the fourth peripheral interconnection 258. That is, a second signal having a potential different from the first signal may be applied to the second lower electrodes ML2_1c through the fourth-first contact plug 257a and the fourth peripheral interconnection 258.

The third-first contact plug 255a may penetrate through the upper surface of the first strap portion GS1 and may be connected to the conductive layer 32 of the first strap portion GS1. A lower surface of the third contact plug 255a may be disposed on a level lower than that of the upper surface of the first strap portion GS1. A lower surface of the fourth-first contact plug 257a may be disposed on a level lower than that of the upper surface of the second strap portion GS2.

The third peripheral interconnection 256 and the fourth peripheral interconnection 258 may extend in the second direction (Y-direction) and may be spaced apart from each other in the second direction (Y-direction).

The third and fourth peripheral interconnections 256 and 258 may be formed in the same process as the first and second peripheral interconnections 252 and 254. The third contact plug 255a and the fourth contact plug 257a may be formed in the same process as the first and second contact plugs 251 and 253.

The semiconductor device 10c may the first and second strap portions provided in the same process as the circuit element, the first lower electrodes connected through the first strap portion, and a capacitor structure including second lower electrodes arranged alternately with the first lower electrodes and connected through a second strap portion. Accordingly, the semiconductor device may form a routing interconnection applied to the capacitor structure through the first and second strap portions extending between the peripheral interconnection and the lower electrode, the semiconductor device with improved integration may be provided.

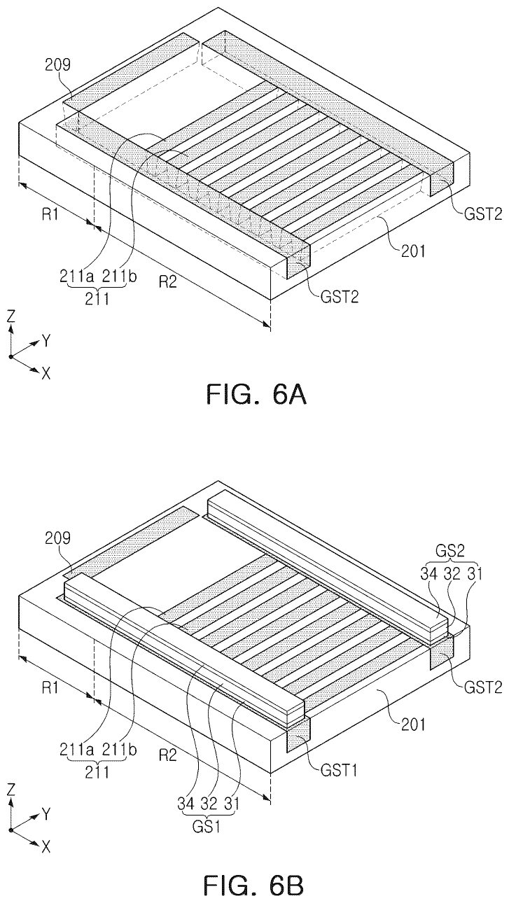

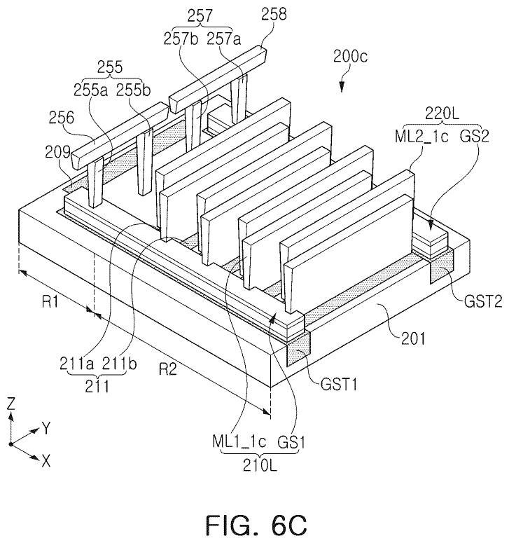

FIGS. 6A, 6B, and 6C are views illustrating an example of a method of manufacturing the semiconductor device of FIG. 5B.

Referring to FIG. 6A, a method of manufacturing a semiconductor device may include an operation of forming an element isolation region 209 in a substrate 201, first and second strap trenches GST1 and GST2, and first and second finger trenches 211a and 211b between the first and second strap trenches GST1 and GST2.

The element isolation region 209 and first and second finger trenches 211a and 211b spaced apart from the element isolation region 209 in the first direction (X-direction) may be formed in the substrate 201. The first and second finger trenches 211a and 211b may be alternately arranged in the first direction (X-direction).

The element isolation region 209 and the first and second finger trenches 211a and 211b may be formed in a shallow trench isolation (STI) process. The shallow trench isolation process may be a process of forming isolation trenches in the substrate 201 and filling the isolation trenches with an insulating material such as silicon oxide.

The first and second strap trenches GST1 and GST2 extending in the first direction (X-direction) between the element isolation region 209 and the first and second finger trenches 211a and 211b in the substrate 201 may be formed through the shallow trench isolation process. In an example, the first and second strap trenches GST1 and GST2 may be formed to extend from the second region R2 to the first region R1. For example, the first and second strap trenches GST1 and GST2 may be formed to extend from the second region R2 to a region adjacent to the element isolation region 209 of the first region R1.

Referring to FIG. 6B, a method of manufacturing a semiconductor device may include an operation of forming the first strap portion GS1 on the first strap trench GST1, and forming the second strap portion GS2 on the second strap portion GST2.

The first strap portion GS1 may be formed to overlap the first strap trench GST1 and extend in the first direction (X-direction). The second strap portion GS2 may be formed to overlap the second strap trench GST2 and extend in the first direction (X-direction). In an example, a process of forming the first and second strap portions GS1 and GS2 may include a process of sequentially forming an insulating layer 31, a conductive layer 32, and a capping layer 34.

The first and second strap portions GS1 and GS2 may be formed in the same process as the circuit element (e.g., the circuit element 230 of FIG. 5C).

Referring to FIG. 6C, a method of manufacturing a semiconductor device includes an operation of forming first lower electrodes ML1_1c on the first strap portion GS1 and second lower electrodes ML2_1c on the second strap portion GS2.

The first lower electrodes ML1_1c and the second lower electrodes ML2_1c may be formed to have a plate shape in which the first lower electrodes ML1_1c and the second lower electrodes ML2_1c are alternated in the first direction (X-direction) and extend in the second direction (Y-direction) and the third direction (Z-direction). In an example, the first and second lower electrodes ML1_1c and ML2_1c may be formed in a damascene process.

The first lower electrodes ML1_1c may be formed on first finger trenches 211a, and the second lower electrodes ML2_1c may be formed on second finger trenches 211b.

The first strap portion GS1 and the first lower electrodes ML1_1C connected through the first strap portion GS1 may form a first lower electrode structure 210L of a capacitor structure 200c. The second strap portion GS2 and the second lower electrodes ML2_1c connected through the second strap portion GS2 may form a second lower electrode structure 220L of the capacitor structure 200c.

The method of manufacturing a semiconductor device may include an operation of forming first contact structures 255 and 256 on the first strap portion GS1, and forming second contact structures 257 and 258 on the second strap portion GS2.

First contact structures 255 and 256 and second contact structures 257 and 258 may be formed in a region between the element isolation region 209 and the first and second lower electrodes ML1_1c and ML2_1c.

The first contact structures 255 and 256 may include a third contact plug 255 and a third peripheral interconnection 256 formed on the third contact plug 255. The third contact plug 255 may include a third-first contact plug 255a disposed on the first strap portion GS1 and a third-two contact plug 255b spaced apart from the third-first contact plug 255a in the second direction (Y-direction). The third-two contact plug 255b may be connected to a circuit element (e.g., the circuit element 230 of FIG. 5C). The third peripheral interconnection 256 may be formed in the form of a line extending in the second direction (Y-direction) on the third contact plug 255.

The second contact structures 257 and 258 may include a fourth contact plug 257 and a fourth peripheral interconnection 258 formed on the fourth contact plug 257. The fourth contact plug 257 may include a fourth-first contact plug 257a disposed on the second strap portion GS2 and a fourth-second contact plug 257b spaced apart from the fourth-first contact plug 257a in the second direction (Y-direction). The fourth-second contact plug 257b may be connected to a circuit element (e.g., the circuit element 230 of FIG. 5B). The fourth peripheral interconnection 258 may be formed in the form of a line extending in the second direction (Y-direction) on the fourth contact plug 257.

The method of manufacturing a semiconductor device may include forming the first and second strap portions in the same process as the circuit element, and forming first lower electrodes connected through the first strap portion and second lower electrodes disposed alternately with the first lower electrodes and connected through the second strap portion, thereby manufacturing the capacitor structure. Accordingly, the first and second strap portions, which are routing interconnections of the capacitor structure, may be formed using the existing circuit element manufacturing process, thereby increasing the integration of the semiconductor device and improve manufacturing process efficiency.

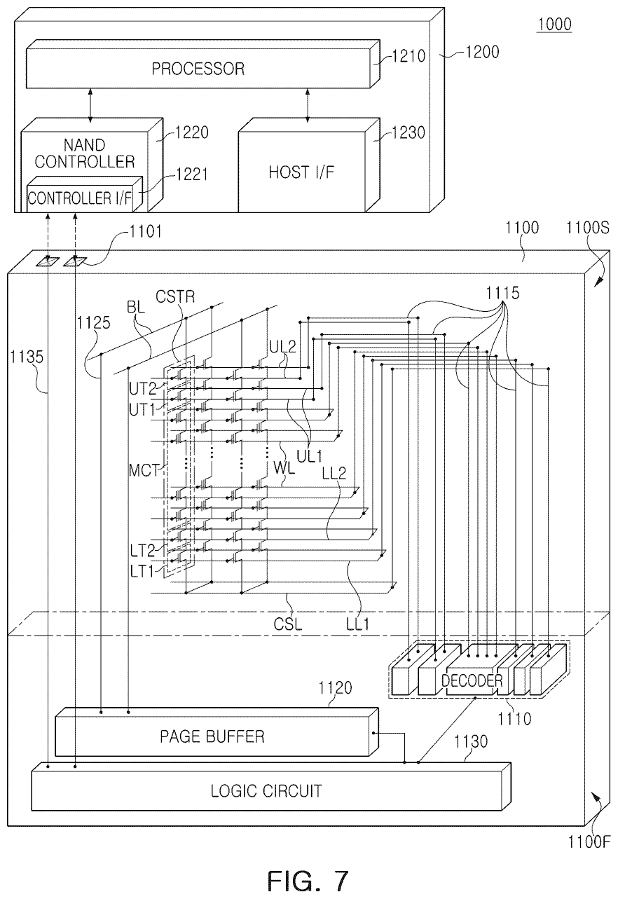

FIG. 7 is a view schematically illustrating an example of a data storage system including a semiconductor device.

Referring to FIG. 7, a data storage system 1000 may include a semiconductor device 1100 and a controller 1200 electrically connected to the semiconductor device 1100. The data storage system 1000 may be a storage device including one or a plurality of semiconductor devices 1100 or an electronic device including the storage device. For example, the data storage system 1000 may be a solid state drive device (SSD) device, a universal serial bus (USB) device, a computing system, a medical device, or a communication device, including one or a plurality of semiconductor devices 1100.

The semiconductor device 1100 may be a non-volatile memory device, for example, the NAND flash memory device described above with reference to FIGS. 1A to 1E. The semiconductor device 1100 may include a first structure 1100F and a second structure 1100S on the first structure 1100F. In some implementations, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to some implementations.

In some implementations, the upper transistors UT1 and UT2 may include a string select transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some implementations, the lower transistors LT1 and LT2 may include a lower erase control transistor LT1 and a ground selection transistor LT2 connected in series. The upper transistors UT1 and UT2 may include a string select transistor UT1 and an upper erase control transistor UT2 connected in series. At least one of the lower erase control transistor LT1 and the upper erase control transistor UT2 may be used in an erase operation to delete data stored in the memory cell transistors MCT using a GIDL phenomenon.

The common source line CSL, the first and second gate lower lines LL1 and LL2, the word lines WL, and the first and second gate upper lines UL1 and UL2 may be electrically connected to the decoder circuit 1110 through first connection interconnections 1115 extending to the second structure 1100S in the first structure 1100F. The bit lines BL may be electrically connected to the page buffer 1120 through second connection interconnections 1125 extending to the second structure 1100S in the first structure 1100F.

In the first structure 1100F, the decoder circuit 1110 and the page buffer 1120 may perform a control operation on at least one selected memory cell transistor among the plurality of memory cell transistors MCT. The decoder circuit 1110 and page buffer 1120 may be controlled by the logic circuit 1130. The semiconductor device 1100 may communicate with the controller 1200 through the input/output pad 1101 electrically connected to the logic circuit 1130. The input/output pad 1101 may be electrically connected to the logic circuit 1130 through an input/output connection interconnection 1135 extending to the second structure 1100S in the first structure 1100F.

The controller 1200 may include a processor 1210, a NAND controller 1220, and a host interface 1230. According to some implementations, the data storage system 1000 may include a plurality of semiconductor devices 1100, and in this case, the controller 1200 may control a plurality of semiconductor devices 1100.

The processor 1210 may control an overall operation of the data storage system 1000, including the controller 1200. The processor 1210 may operate according to predetermined firmware, and may control the NAND controller 1220 to access the semiconductor device 1100. The NAND controller 1220 may include a controller interface 1221 configured to process communication with the semiconductor device 1100. Through the controller interface 1221, control commands for controlling the semiconductor device 1100, data to be recorded in the memory cell transistors (MCT) of the semiconductor device 1100, and data to be read from the memory cell transistors MCT of the semiconductor device 1100 may be transmitted. The host interface 1230 may provide a communication function between the data storage system 1000 and an external host. When receiving a control command from the external host through the host interface 1230, the processor 1210 may control the semiconductor device 1100 in response to control commands.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made within a scope not departing from the spirit and region of the present disclosure as defined by the appended claims.

What is claimed is:

1. A semiconductor device, comprising:
a first semiconductor structure including a substrate, an active region within the substrate, a plurality of circuit elements on the substrate, an element isolation region defining the active region, a plurality of impurity regions disposed within the active region on both sides of the plurality of circuit elements, an interconnection structure electrically connected with the plurality of circuit elements, and a capacitor structure spaced apart from the interconnection structure in a first direction; and
a second semiconductor structure including a plate layer disposed on the first semiconductor structure, a plurality of gate electrodes sequentially stacked and spaced apart from each other in a perpendicular direction on the plate layer, and a plurality of channel structures, the perpendicular direction being perpendicular to an upper surface of the plate layer, and the plurality of channel structures extending through the plurality of gate electrodes in the perpendicular direction,
wherein the capacitor structure includes:
a first electrode structure including a first strap portion and a plurality of first electrodes, the first strap portion disposed on the substrate, the first electrode structure extending in the first direction, the plurality of first electrodes extending from the first strap portion in a second direction, the second direction intersecting the first direction; and
a second electrode structure including a second strap portion and a plurality of second electrodes, the second strap portion extending on the substrate in the first direction and spaced apart from the first strap portion in the second direction, the plurality of second electrodes extending from the second strap portion in the second direction and arranged alternately with the plurality of first electrodes,
wherein the plurality of first electrodes have a plate shape extending from an upper surface of the first strap portion in a vertical direction, the vertical direction intersecting the first direction and the second direction, and
wherein the plurality of second electrodes have a plate shape extending from an upper surface of the second strap portion in the vertical direction.

2. The semiconductor device of claim 1, wherein each circuit element of the plurality of circuit elements includes a gate structure and a gate electrode, the gate structure including a gate insulating layer on the substrate, and the gate electrode being on the gate insulating layer,
wherein the first strap portion and the second strap portion include an insulating layer extending in the first direction and a conductive layer on the insulating layer, and
wherein an upper surface of the first strap portion and an upper surface of the second strap portion are disposed on substantially the same level as an upper surface of the gate structure.

3. The semiconductor device of claim 1, wherein the first strap portion and the second strap portion include a first conductive material, and the plurality of first electrodes and the plurality of second electrodes include a second conductive material different from the first conductive material.

4. The semiconductor device of claim 1, wherein the interconnection structure includes a first contact structure and a second contact structure, the first contact structure electrically connected with the first electrode structure and the second contact structure electrically connected with the second electrode structure,
wherein the first contact structure includes a first contact plug and a first contact line, the first contact plug disposed on the first strap portion and the first contact line extending on the first contact plug in the second direction, and
wherein the second contact structure includes a second contact plug and a second contact line, the second contact plug disposed on the second strap portion and the second contact line extending on the second contact plug in the second direction.

5. The semiconductor device of claim 1, wherein a lower surface of the plurality of first electrodes extends through a portion of the first strap portion and faces a lower surface of the first strap portion, and
wherein a lower surface of the plurality of second electrodes extends through a portion of the second strap portion and faces a lower surface of the second strap portion.

6. The semiconductor device of claim 1, comprising:
a first strap trench extending within the substrate in the first direction and overlapping the first strap portion;
a second strap trench extending within the substrate in the first direction, spaced apart from the first strap trench in the second direction, and overlapping the second strap portion; and
at least one finger trench extending between the first strap trench and the second strap trench within the substrate in the second direction, the at least one finger trench connecting the first strap trench and the second strap trench, and the at least one finger trench overlapping the plurality of first electrodes and the plurality of second electrodes,
wherein the first strap trench, the second strap trench, and the at least one finger trench are filled with an insulating material.

7. The semiconductor device of claim 6, wherein the at least one finger trench includes a first finger trench and a second finger trench, the first finger trench overlapping each of the plurality of first electrodes, and the second finger trench overlapping each of the plurality of second electrodes and spaced apart from the first finger trench in the first direction.

8. The semiconductor device of claim 6, wherein an upper surface of the at least one finger trench is disposed on the same level as an upper surface of the element isolation region.

9. The semiconductor device of claim 1, wherein the interconnection structure includes a third contact plug and a third contact interconnection, the third contact plug disposed on an impurity region and the third contact interconnection disposed on the third contact plug and extending in the second direction, and
wherein an upper surface of the third contact interconnection is disposed on a level higher than a level of an upper surface of the plurality of first electrodes and a level of an upper surface of the plurality of second electrodes.

10. The semiconductor device of claim 1, wherein the first electrode structure includes a plurality of first intermediate electrodes disposed on the plurality of first electrodes and a plurality of first upper electrodes disposed on the plurality of first intermediate electrodes,
wherein the second electrode structure includes second intermediate electrodes disposed on the second electrodes and second upper electrodes disposed on the second intermediate electrodes,
wherein the first intermediate electrodes and the second intermediate electrodes are spaced apart from each other in the first direction and alternately arranged, and have a plate shape extending in the vertical direction, and
wherein the first upper electrodes and the second upper electrodes are spaced apart from each other in the first direction and alternately arranged, and have the plate shape extending in the vertical direction.

11. The semiconductor device of claim 1, wherein a separation distance between the first strap portion and the second strap portion in the second direction is substantially equal to a width of the first electrodes in the second direction.

12. A semiconductor device, comprising:
a substrate including an active region;
a plurality of circuit elements on the active region;
an element isolation region defining the active region;
a plurality of impurity regions disposed within the active region on both sides of the plurality of circuit elements;
a capacitor structure spaced apart from the plurality of circuit elements; and
a first finger trench spaced apart from the plurality of circuit elements and extending within the substrate in a first direction, and a second finger trench extending in the first direction and arranged alternately with the first finger trench,
wherein the capacitor structure includes:
a plurality of first lower electrodes disposed on the first finger trench; and
a plurality of second lower electrodes disposed on the second finger trench and arranged alternately with the plurality of first lower electrodes,
wherein the plurality of first lower electrodes and the plurality of second lower electrodes have a plate shape extending in the first direction and a vertical direction, the vertical direction intersecting the first direction, and
wherein an upper surface of the first finger trench and an upper surface of the second finger trench are disposed on the same level as an upper surface of the element isolation region.

13. The semiconductor device of claim 12, wherein the first finger trench and the second finger trench are arranged alternately at a plurality of regular intervals.

14. The semiconductor device of claim 12, wherein a lower surface of the plurality of first lower electrodes and a lower surface of the plurality of second lower electrodes are disposed on a level lower than a level of the upper surface of the first finger trench and a level of the upper surface of the second finger trench.

15. The semiconductor device of claim 12, comprising:
a first intermediate interconnection disposed on the plurality of first lower electrodes; and
a second intermediate interconnection disposed on the plurality of second lower electrodes,
wherein a height of the first intermediate interconnection and the second intermediate interconnection in the vertical direction is lower than a height of the plurality of first lower electrodes and the plurality of second lower electrodes in the vertical direction.

16. The semiconductor device of claim 12, comprising:
an interconnection structure electrically connected with the plurality of circuit elements,
wherein the interconnection structure includes a third contact plug and a third contact line, the third contact plug disposed on the impurity region and the third contact line disposed on the third contact plug and extending in the first direction, and
wherein an upper surface of the third contact line is disposed on a level higher than a level of an upper surface of the plurality of first lower electrodes and a level of an upper surface of the plurality of second lower electrodes.

17. The semiconductor device of claim 12, comprising:
a first intermediate electrode structure disposed on the plurality of first lower electrodes; and
a second intermediate electrode structure disposed on the plurality of second lower electrodes,
wherein the first intermediate electrode structure includes a first connection portion and a plurality of first intermediate electrodes, the first connection portion extending in a second direction, the second direction intersecting the first direction, and the plurality of first intermediate electrodes extending from the first connection portion in the first direction and overlapping the plurality of first lower electrodes, and
wherein the second intermediate electrode structure includes a second connection portion and a plurality of second intermediate electrodes, the second connection portion extending in the second direction, and the plurality of second intermediate electrodes extending from the second connection portion in the first direction and overlapping the plurality of second lower electrodes.

18. The semiconductor device of claim 12, comprising:
a first strap portion extending on the substrate in a second direction, the second direction intersecting the first direction, and the first strap portion connecting the plurality of first lower electrodes; and
a second strap portion extending in the second direction, connecting the plurality of second lower electrodes, and spaced apart from the first strap portion in the first direction,
wherein the plurality of first lower electrodes extend in the vertical direction through a portion of an upper surface of the first strap portion, and
wherein the plurality of second lower electrodes extend in the vertical direction through a portion of an upper surface of the second strap portion.

19. A semiconductor device, comprising:
a substrate including an active region;
a plurality of circuit elements including a gate structure on the active region;
an element isolation region defining the active region;
a plurality of impurity regions disposed within the active region on both sides of the plurality of circuit elements; and
a capacitor structure spaced apart from the plurality of circuit elements,
wherein the capacitor structure includes:
a first electrode structure including a first strap portion and a plurality of first electrodes, the first strap portion disposed on the substrate and extending in a first direction, and the plurality of first electrodes extending from the first strap portion in a second direction, the second direction intersecting the first direction; and
a second electrode structure including a second strap portion and a plurality of second electrodes, the second strap portion extending on the substrate in the first direction and spaced apart from the first strap portion in the second direction, and the plurality of second electrodes extending from the second strap portion in the second direction and arranged alternately with the plurality of first electrodes,
wherein an upper surface of the first strap portion and an upper surface of the second strap portion are disposed on at the same level as an upper surface of the gate structure.

20. The semiconductor device of claim 19, comprising:
a first contact structure electrically connected with the first electrode structure and a second contact structure electrically connected with the second electrode structure,
wherein the first contact structure includes a first contact plug and a first contact line, the first contact plug disposed on the first strap portion and the first contact line extending on the first contact plug in the second direction, and
wherein the second contact structure includes a second contact plug and a second contact line, the second contact plug disposed on the second strap portion and the second contact line extending on the second contact plug in the second direction.
